(19) United States
(12) Patent Application Publication
(10) Pub. No.: US 2025/0241008 A1
(43) Pub. Date: Jul. 24, 2025

(54) THIN FILM TRANSISTOR, THIN FILM TRANSISTOR SUBSTRATE, METHOD FOR MANUFACTURING THE SAME AND DISPLAY APPARATUS COMPRISING THE SAME

(71) Applicant: LG Display Co., Ltd., Seoul (KR)

(72) Inventors: Jaeman Jang, Paju-si (KR); Younghyun Ko, Paju-si (KR); Uyhyun Choi, Paju-si (KR); Jinwon Jung, Paju-si (KR); Jihee Ryu, Paju-si (KR)

(73) Assignee: LG Display Co., Ltd., Seoul (KR)

(21) Appl. No.: 18/986,325

(22) Filed: Dec. 18, 2024

(30) Foreign Application Priority Data
Dec. 19, 2023 (KR) 10-2023-0185835

(51) Int. Cl. H10D 30/67; H10D 30/01; H10D 62/53; H10D 86/40; H10D 86/60

(52) U.S. Cl. CPC H10D 30/6713; H10D 30/031; H10D 30/6723; H10D 30/6755; H10D 62/53; H10D 86/421; H10D 86/60

(57) ABSTRACT

A thin film transistor, a thin film transistor substrate, a method of manufacturing a thin film transistor and a display apparatus including the thin film transistor are provided. The thin film transistor includes a base substrate, an active material layer on the base substrate, and a gate electrode spaced apart from the active material layer and overlapping at least a portion of the active material layer. The active material layer includes a channel portion overlapping the gate electrode, a source connection portion contacting one side of the channel portion, a drain connection portion contacting the other side of the channel portion and an insulating portion contacting at least one of the source connection portion and the drain connection portion. Further, the channel portion, the source connection portion, the drain connection portion, and the insulating portion are disposed on a same layer.

### CROSS-REFERENCE TO RELATED APPLICATIONS

This application claims priority to Korean Patent Application No. 10-2023-0185835, filed in the Republic of Korea on Dec. 19, 2023, the entirety of which is hereby expressly incorporated by reference into the present application.

### BACKGROUND

### Technical Field

The present disclosure relates to a thin film transistor, a thin film transistor substrate, a method of manufacturing a thin film transistor, and a display apparatus including a thin film transistor.

### Discussion of the Related Art

Transistors are widely used as switching devices or driving devices in the electronic field. In particular, since thin film transistors (TFTs) can be manufactured on a glass base substrate or a plastic base substrate, they can be used as a switching device of a display apparatus such as a liquid crystal display apparatus or an organic light emitting devices.

Based on the material constituting the active material layer, the thin film transistors can be classified as an amorphous silicon thin film transistor in which amorphous silicon is used as the active material layer, a polycrystalline silicon thin film transistor in which polycrystalline silicon is used as the active material layer, and an oxide semiconductor thin film transistor in which oxide semiconductor used as the active material layer.

Among these thin film transistors, an oxide semiconductor thin film transistor (oxide semiconductor TFT), which has a high mobility and can have large resistance changes depending on the oxygen content, has an advantage in that desired properties can easily be obtained. In addition, the manufacturing cost of an oxide semiconductor thin film transistor is low because the oxide constituting the active layer can be formed at a relatively low temperature during the manufacturing process of the oxide semiconductor thin film transistor. Due to the nature of oxide, oxide semiconductor is transparent, thus the oxide semiconductor thin film transistor is advantageous for embodying a transparent display apparatus.

In order to apply an oxide semiconductor to a thin film transistor, it is necessary to pattern the oxide semiconductor layer and conductorize a portion of the patterned oxide semiconductor layer. However, during the patterning process and subsequent processes, loss or deterioration can occur at the edge of the oxide semiconductor pattern or at the insulating layer. In case when such loss or deterioration occurs, the stability of the thin film transistor can deteriorate.

Recently, in order to maximize the advantages of oxide semiconductor thin film transistors, research is being conducted to improve the stability and electrical characteristics of oxide thin film transistor and to reduce manufacturing costs of oxide semiconductor thin film transistor.

### SUMMARY OF THE DISCLOSURE

An aspect of the present disclosure is to provide a thin film transistor that can be manufactured without patterning the active material layer and a thin film transistor substrate including the same.

Another aspect of the present disclosure is to provide a thin film transistor and a thin film transistor substrate having an insulating portion formed by doping a dopant instead of patterning an active material layer, and a channel portion, a source connection portion, and a drain connection portion are implemented by the insulating portion.

Another aspect of the present disclosure is to provide a method of manufacturing a thin film transistor and a method of manufacturing a thin film transistor substrate, in which a same effect as patterning is achieved by forming an insulating portion by doping a dopant without patterning the active material layer.

Another aspect of the present disclosure is to provide a display apparatus including the thin film transistor as described above, and thus having excellent reliability.

In accordance with an aspect of the present disclosure, the above and other objects can be accomplished by the provision of a thin film transistor comprising an active material layer on a base substrate and a gate electrode spaced apart from the active material layer and overlapping at least a part of the active material layer, wherein the active material layer includes a channel portion overlapping the gate electrode, a source connection portion contacting one side of the channel portion, a drain connection portion contacting the other side of the channel portion and an insulating portion contacting at least one of the source connection portion and the drain connection portion, and wherein the channel portion, the source connection portion, the drain connection portion, and the insulating portion are disposed on a same layer.

According to aspects of the present disclosure, the active material layer can include an oxide semiconductor material, and the insulating portion can include a first dopant.

According to aspects of the present disclosure, the first dopant can include at least one of nitrogen (N), sulfur(S), chlorine (Cl), gallium (Ga), tungsten (W), iron (Fc), and tin (Sn).

According to aspects of the present disclosure, the first dopant can include nitrogen (N), and the insulating portion can include 40 to 60 atomic % (at %) of oxygen and 4 to 10 atomic % (at %) of nitrogen based on the total number of atoms of the insulating portion.

According to aspects of the present disclosure, each of the source connection portion and the drain connection portion can include a second dopant different from the first dopant.

According to aspects of the present disclosure, the second dopant can include at least one of boron (B), phosphorus (P), fluorine (F) and hydrogen (H).

According to aspects of the present disclosure, the insulating portion can further include the second dopant.

According to aspects of the present disclosure, the oxide semiconductor material can include at least one of IGZO (InGaZnO)-based, IGZTO (InGaZnSnO)-based, IZO (InZnO)-based, IGO (InGaO)-based, ITO (InSnO)-based, ITZO (InSnZnO)-based, InO-based, ZnO-based and FIZO (FelnZnO)-based oxide semiconductor material.

According to aspects of the present disclosure, the active material layer may not be patterned.

According to aspects of the present disclosure, the channel portion, the source connection portion, the drain connection portion, and the insulating portion are integrally formed.

According to aspects of the present disclosure, the thin film transistor can further include a light shielding layer disposed between the base substrate and the active material layer and overlapping the channel portion.

According to aspects of the present disclosure, the thin film transistor can further include a first capacitor electrode integrally formed with the light shielding layer and not overlapping the channel portion.

According to aspects of the present disclosure, the active material layer can include a second capacitor electrode spaced apart from the channel portion, and the second capacitor electrode is insulated from at least one of the source connection portion and the drain connection portion by the insulating portion, and wherein the first capacitor electrode and the second capacitor electrode overlap each other to form a first capacitor. Further, the oxide semiconductor material can include gallium (Ga), and the first dopant includes gallium (Ga). Further, the concentration of gallium (Ga) included in the insulating portion can be higher than the concentration of gallium (Ga) included in the channel portion, the source connection portion, or the drain connection portion. Further, the active material layer can include a first oxide semiconductor material layer, and a second oxide semiconductor material layer on the first oxide semiconductor material layer.

Another embodiment of the present disclosure provides a thin film transistor substrate comprising a first thin film transistor and a second thin film transistor on a base substrate, wherein the first thin film transistor and the second thin film transistor include an active material layer, wherein the first thin film transistor includes a first channel portion on the base substrate, a first source connection portion contacting one side of the first channel portion, a first drain connection portion contacting the other side of the first channel portion, and a first gate electrode spaced apart from the active material layer and overlapping the first channel portion, wherein the second thin film transistor includes, a second channel portion on the base substrate, a second source connection portion contacting one side of the second channel portion, a second drain connection portion contacting the other side of the second channel portion, and a second gate electrode spaced apart from the active material layer and overlapping the second channel portion, wherein the first thin film transistor and the second thin film transistor are spaced apart from each other with an insulating portion interposed therebetween, the active material layer includes the first channel portion, the first source connection portion, the first drain connection portion, the second channel portion, the second source connection portion, the second drain connection portion and the insulating portion, and the first channel portion, the first source connection portion, the first drain connection portion, the second channel portion, the second source connection portion, the second drain connection portion and the insulating portion are disposed on a same layer.

According to aspects of the present disclosure, the first channel portion, the first source connection portion, the first drain connection portion, the second channel portion, the second source connection portion, the second drain connection portion and the insulating portion can be integrally formed.

According to aspects of the present disclosure, the first channel portion, the first source connection portion, the first drain connection portion, the second channel portion, the second source connection portion, the second drain connection portion and the insulating portion include an oxide semiconductor material, and wherein the insulating portion can further include a first dopant.

According to aspects of the present disclosure, the first dopant can include at least one of nitrogen (N), sulfur(S), chlorine (Cl), gallium (Ga), tungsten (W), iron (Fe), and tin (Sn).

According to aspects of the present disclosure, the first source connection portion, the first drain connection portion, the second source connection portion and the second drain connection portion can include a second dopant different from the first dopant.

Another embodiment of the present disclosure provides a display apparatus comprising the thin film transistor substrate and light emitting element.

Another embodiment of the present disclosure provides a display apparatus comprising a plurality of pixels arranged on a base substrate, wherein each of the plurality of pixels includes a display element and a pixel driving circuit to drive the display element, wherein the pixel driving circuit includes the thin film transistor described above.

According to aspects of the present disclosure, the active material layer can be formed integrally over the plurality of pixels.

Another embodiment of the present disclosure provides a method of manufacturing a thin film transistor, the method comprises forming an active material layer on a base substrate, forming a mask on the active material layer, forming an insulating portion by doping a first dopant into a part of the active material layer that does not overlap the mask, forming a gate electrode spaced apart from the active material layer on the active material layer, and forming a source connection portion and a drain connection portion by conductorizing parts of the active material layer not overlapping the gate electrode, wherein a part of the active material layer overlapping the gate electrode forms a channel portion, wherein the source connection portion is disposed between the channel portion and the insulating portion, and the drain connection portion is spaced apart from the source connection portion and disposed between the channel portion and the insulating portion.

According to aspects of the present disclosure, the first dopant can include at least one of nitrogen (N), sulfur(S), chlorine (Cl), gallium (Ga), tungsten (W), iron (Fe), and tin (Sn).

According to aspects of the present disclosure, the conductorization is performed by plasma treatment or doping with a second dopant.

According to an embodiment of the present disclosure, since the thin film transistor can be manufactured without patterning the active material layer, defects that can occur during the patterning of the active material layer can be avoided. As a result, the stability of the thin film transistor is improved.

In addition, because a channel portion, a source connection portion, a drain connection portion, and an insulating portion can be implemented with one active material layer, the channel portion, the source connecting portion, the drain connecting portion, and the insulating portion can be implemented integrally with one material.

According to an embodiment of the present disclosure, the active area of the thin film transistor can be defined by an insulating portion formed by doping a dopant without patterning the active material layer. Since the patterning process to the active material layer can be omitted, process efficiency is improved, the use of harmful substances for the etching process can be reduced, and thus the process of manufacturing the thin film transistor is environmentally friendly.

Since the thin film transistor according to an embodiment of the present disclosure can be manufactured without patterning, defects are reduced and the thin film transistor can have excellent reliability. In addition, a display apparatus according to another embodiment of the present disclosure including the thin film transistor has excellent reliability, and can have excellent display performance.

In addition to the effects mentioned above, other features and advantages of the present disclosure are described below. From the description and explanation, present disclosure will be clearly understood by those skilled in the art.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features and other advantages of the present disclosure will be more clearly understood from the following detailed description taken in conjunction with the accompanying drawings.

FIG. 1 is a plan view of a thin film transistor according to an embodiment of the present disclosure.

FIG. 2 is a cross-sectional view along IA-IA′ of FIG. 1.

FIG. 3 is a cross-sectional view along IB-IB′ of FIG. 1.

FIGS. 4A and 4B are diagrams illustrating bonding states of nitrogen (N) doped in an oxide semiconductor material, respectively.

FIG. 5 is a schematic diagram illustrating oxygen vacancy.

FIG. 6 is a schematic diagram illustrating a mechanism in which oxygen vacancies are removed by nitrogen (N) doping.

FIG. 7 is a schematic diagram illustrating a change in band gap state due to nitrogen-oxygen bonding (N—O bonding).

FIG. 8A is a graph illustrating a change in carrier density of an oxide semiconductor material depending on nitrogen concentration. FIG. 8B is a graph illustrating a change in mobility and surface resistance of an oxide semiconductor material depending on nitrogen concentration.

FIG. 8C illustrates the resistance of the oxide semiconductor material depending on the concentration of oxygen and nitrogen.

FIG. 9 is a cross-sectional view of a thin film transistor according to another embodiment of the present disclosure.

FIG. 10 is a cross-sectional view of a thin film transistor according to another embodiment of the present disclosure.

FIG. 11 is a cross-sectional view of a thin film transistor according to another embodiment of the present disclosure.

FIG. 12 is a cross-sectional view of a thin film transistor according to another embodiment of the present disclosure.

FIG. 13A is a cross-sectional view of a thin film transistor substrate according to another embodiment of the present disclosure.

FIG. 13B is a plan view of the active material layer of FIG. 13A.

FIG. 14 is a cross-sectional view of a thin film transistor substrate according to another embodiment of the present disclosure.

FIGS. 15A to 15F are cross-sectional views illustrating a manufacturing process of a thin film transistor substrate according to another embodiment of the present disclosure.

FIG. 16 is a schematic diagram of a display apparatus according to another embodiment of the present disclosure.

FIG. 17 is a circuit diagram of a pixel of FIG. 16.

FIG. 18 is a plan view of the pixel of FIG. 17.

FIG. 19 is a cross-sectional view along II-II′ of FIG. 18.

FIG. 20 is a circuit diagram for a pixel of a display apparatus according to another embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully explain the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout the disclosure. In the following description, when the detailed description of the relevant known function or configuration is determined to unnecessarily obscure the important point of the present disclosure, the detailed description will be omitted. Further, the term “can” fully encompasses all the meanings and coverages of the term “may.”

In a case where ‘comprise’, ‘have’, and ‘include’ described in the present disclosure are used, another part can be added unless ‘only’ is used. The terms of a singular form can include plural forms unless referred to the contrary.

In construing an element, the element is construed as including an error range although there is no explicit description.

In describing a position relationship, for example, when the position relationship is described as ‘on’, ‘over’, ‘upon’, ‘above’, ‘below’, and ‘next to’, one or more portions can be arranged between two other portions unless ‘just’ or ‘directly’ is used.

Spatially relative terms such as “below”, “beneath”, “lower”, “above”, and “upper” can be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below”, or “beneath” another device can be arranged “above” another device. Therefore, an exemplary term “below or beneath” can include “below or beneath” and “above” orientations. Likewise, an exemplary term “above” or “on” can include “above” and “below or beneath” orientations.

In describing a temporal relationship, for example, when the temporal order is described as “after,” “subsequent,” “next,” and “before,” a case which is not continuous can be included, unless “just” or “direct” is used.

It will be understood that, although the terms “first”, “second”, etc. can be used herein to describe various elements, these elements should not be limited by these terms. These terms are only used to partition one element from another and may not define order or sequence. For example, a first element could be termed a second element, and, similarly, a second element could be termed a first element, without departing from the scope of the present invention.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

Hereinafter, a thin film transistor and a display apparatus including the same according to various embodiments of the present disclosure will be described in detail with reference to the attached drawings. All the components of each apparatus/device according to all embodiments of the present disclosure are operatively coupled and configured. In the drawings, the same or similar elements are denoted by the same reference numerals even though they are depicted in different drawings.

In the embodiments of the present disclosure, a source electrode and a drain electrode are distinguished from each other, for convenience of description. However, the source electrode and the drain electrode can be used interchangeably. The source electrode can be the drain electrode, and the drain electrode can be the source electrode. Further, the source electrode in any one embodiment of the present disclosure can be the drain electrode in another embodiment of the present disclosure, and the drain electrode in any one embodiment of the present disclosure can be the source electrode in another embodiment of the present disclosure.

In some embodiments of the present disclosure, for convenience of explanation, a source region and a source electrode are distinguished, and a drain region and a drain electrode are distinguished, but the embodiments of the present disclosure are not limited thereto. The source region can be a source electrode, and the drain region can be a drain electrode. In addition, the source region can be a drain electrode, and the drain region can be a source electrode.

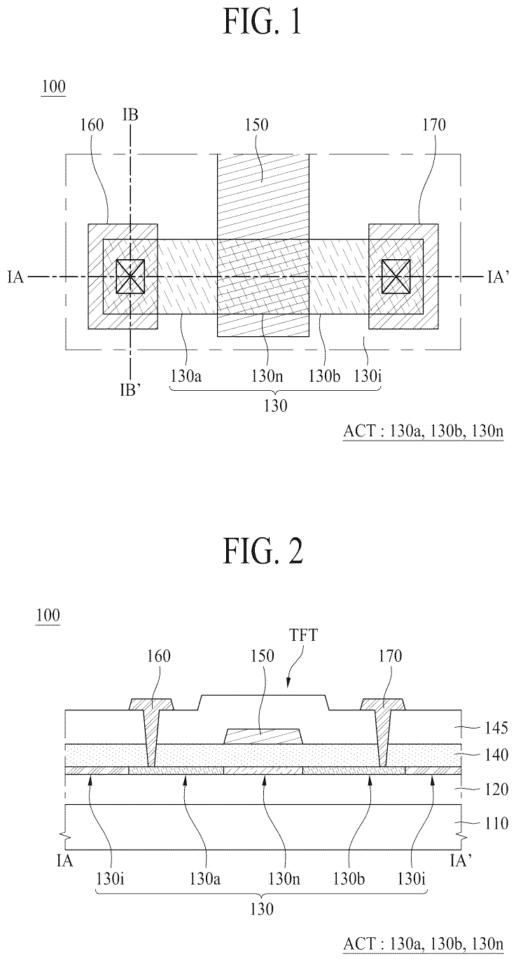

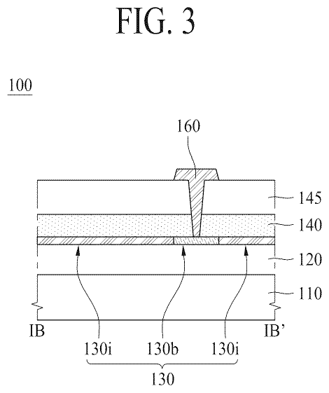

FIG. 1 is a plan view of a thin film transistor 100 according to an embodiment of the present disclosure, FIG. 2 is a cross-sectional view along IA-IA′ of FIG. 1, and FIG. 3 is a cross-sectional view along IB-IB′ of FIG. 1.

Referring to FIGS. 1, 2, and 3, the thin film transistor 100 according to an embodiment of the present disclosure includes an active material layer 130 on a base substrate 110, and a gate electrode 150 that is spaced apart from the active material layer 130 and at least partially overlaps the active material layer 130. In addition, the thin film transistor 100 can include a source electrode 160 and a drain electrode 170 that are spaced apart from each other and are respectively connected to the active material layer 130.

The active material layer 130 includes a channel portion 130n overlapping the gate electrode 150, a source connection portion 130a contacting one side of the channel portion 130n, a drain connection portion 130b contacting the other side of the channel portion 130n, and an insulating portion 130i in contact with at least one of the source connection portion 130a and the drain connection portion 130b.

According to an embodiment of the present disclosure, a thin film transistor TFT can be configured by the channel portion 130n, the source connection portion 130a, the drain connection portion 130b, the gate electrode 150, the source electrode 160, and the drain electrode 170. The thin film transistor 100 can be disposed on the base substrate 110.

The base substrate 110 supports the components of the thin film transistor 100. Anything that supports a thin-film transistor TFT can be referred to as a base substrate 110 without limitation.

Glass or plastic can be used as the base substrate 110. A transparent plastic with flexible properties, for example, a polyimide, can be used as the plastic. When polyimide is used as the base substrate 110, considering that a high temperature deposition process is performed on the base substrate 110, a heat-resistant polyimide that can withstand high temperatures can be used.

A light shielding layer 111 can be disposed on the base substrate 110 (see FIG. 11). The light shielding layer can be omitted.

Referring to FIGS. 2 and 3, a buffer layer 120 is disposed on the base substrate 110. The buffer layer 120 can be made of an insulating material. For example, the buffer layer 120 can include at least one of insulating material selected from silicon oxide, silicon nitride, and metal-based oxide. The buffer layer 120 can have a single-layer structure or a multi-layer structure.

The buffer layer 120 blocks air and moisture and thus can protect channel portion 130n. In addition, the surface over the base substrate 110 can be made uniform by the buffer layer 120.

The active material layer 130 is disposed on the base substrate 110. Referring to FIGS. 2 and 3, the active material layer 130 can be disposed on the buffer layer 120, which is disposed on the base substrate 110.

According to an embodiment of the present disclosure, the channel portion 130n, the source connection portion 130a, the drain connection portion 130b and the insulating portion 130i, which are included in the active material layer 130, can all be disposed on a same layer. The channel portion 130n, the source connection portion 130a, the drain connection portion 130b, and the insulating portion 130i can be formed integrally. Each region of the active material layer 130 can be distinguished by doping.

According to an embodiment of the present disclosure, the active material layer 130 can include an oxide semiconductor material. In detail, the channel portion 130n, the source connection portion 130a, the drain connection portion 130b, and the insulating portion 130i can include an oxide semiconductor material.

Oxide semiconductor material can include at least one of, for example, IGZO (InGaZnO)-based, IGZTO (InGaZnSnO)-based, IZO (InZnO)-based, IGO (InGaO)-based, ITO (InSnO)-based, ITZO (InSnZnO)-based, InO-based, ZnO-based and FIZO (FelnZnO)-based oxide semiconductor material. However, the embodiment of the present disclosure is not limited thereto, and the active material layer 130 can include other oxide semiconductor materials known in the art.

The channel portion 130n overlaps the gate electrode 150. The channel portion 130n has semiconductor characteristics. Depending on the voltage applied to the gate electrode 150, the channel portion 130n can have conductor-like electrical characteristics or insulator-like characteristics. For example, when the thin film transistor TFT is in an OFF state, the channel portion 130n can have a resistivity in a range of 10⁻⁴ Ω·cm to 10⁴ Ω·cm.

According to an embodiment of the present disclosure, each of the source connection portion 130a and the drain connection portion 130b may0 have electrical characteristics similar to that of a conductor. For example, each of the source connection portion 130a and the drain connection portion 130b can have a resistivity of 10⁻⁴ Ω·cm or less. The source connection portion 130a and the drain connection portion 130b can each have a substantially constant resistivity regardless of whether the thin film transistor TFT is turned on or turned off.

According to an embodiment of the present disclosure, the source connection portion 130a and the drain connection portion 130b can be referred to as a conductor region.

According to an embodiment of the present disclosure, the insulating portion 130i can have insulating properties. The insulating portion 130i can have a resistivity of, for example, 10⁷ Ω·cm or more. In detail, the insulating portion 130i can have a resistivity of 10⁸ Ω·cm or more. In more detail, the insulating portion 130i can have a resistivity of 10⁷ to 10²⁰ Ω·cm, or a resistivity of 10⁸ to 10¹⁸ Ω·cm. The insulating portion 130i can have a substantially constant resistivity regardless of whether the thin film transistor TFT is turned on or turned off.

According to an embodiment of the present disclosure, the insulating portion 130i can be referred to as an insulating region.

According to an embodiment of the present disclosure, the insulating portion 130i can include a first dopant. The active material layer 130 can be selectively doped with the first dopant to form the insulating portion 130i. In detail, the insulating portion 130i can be formed by selectively doping the oxide semiconductor material constituting the active material layer 130 with the first dopant. According to an embodiment of the present disclosure, a region of the active material layer 130 doped with the first dopant can be referred to as an insulating portion 130i.

The first dopant serves to increase the resistance of the oxide semiconductor material. For example, the first dopant can serve to remove oxygen vacancies occurring in the oxide semiconductor material. By removing oxygen vacancies by the first dopant, the carrier density of the oxide semiconductor material can be reduced, and the mobility and electrical conductivity of the oxide semiconductor material can be reduced. As a result, the region of the oxide semiconductor material doped with the first dopant can have insulating properties. According to an embodiment of the present disclosure, the carrier density is also known as carrier concentration, and denotes the number of charge carriers per volume.

The insulating portion 130i is a region, where the active material layer 130 is selectively doped with the first dopant, and can be defined as a portion having a very low carrier density and thus insulating properties. The insulating portion 130i has a low carrier density, and has a low mobility and a high resistance compared to other regions of the active material layer 130.

According to an embodiment of the present disclosure, the first dopant can include at least one of nitrogen (N), sulfur(S), chlorine (Cl), gallium (Ga), tungsten (W), iron (Fe) and tin (Sn). For example, nitrogen (N) used as the first dopant can be doped into the oxide semiconductor material constituting the active material layer 130 and can be disposed at a location where oxygen vacancies occur. Accordingly, carriers generated by oxygen vacancies can be trapped by nitrogen (N). By trapping carriers, the carrier density and the mobility of the doped region are lowered, and resistance of the doped region is increased. Accordingly, the nitrogen (N)-doped portion can have insulating properties. Under this condition, the carrier generated by oxygen vacancy is an electron (e−).

In addition, at least one of the first dopant, which are non-metallic elements sulfur(S) and chlorine (Cl), can be doped into the oxide semiconductor material and disposed at a location where oxygen vacancy occurs. Accordingly, carriers generated by oxygen vacancies are trapped by sulfur(S) or chlorine (Cl), so that the portion doped with the first dopant can have insulating properties. Accordingly, a portion of the active material layer 130 doped with at least one of sulfur(S) and chlorine (Cl) can become the insulating portion 130i.

When at least one of the first dopants, which are metal elements gallium (Ga), tungsten (W), iron (Fe), and tin (Sn), is doped into an oxide semiconductor material, the metal-oxygen bond can be increased in the doped region. Accordingly, the region of the oxide semiconductor material, which is doped with at least one of gallium (Ga), tungsten (W), iron (Fe), and tin (Sn) becomes an oxide of oxygen (O)-saturated state, and thus can have insulating properties.

For example, in an oxygen atmosphere, which is under O2 gas state, when an indium (In)-based oxide semiconductor material containing indium (In) is doped with metal elements such as gallium (Ga), tungsten (W), iron (Fe), and tin (Sn), the doped metal element replaces indium (In), and at the same time, the doped metal element can combine with oxygen (O). As a result, indium (In) can be removed from the doped region of the oxide semiconductor material, thereby lowering the carrier density. In addition, because doped metal elements can form strong bonds with oxygen, the region of the oxide semiconductor material doped with metal elements such as gallium (Ga), tungsten (W), iron (Fe), and tin (Sn) becomes oxygen-rich oxide, and the insulation of the doped region can increase. Accordingly, a portion of the active material layer 130 doped with at least one of gallium (Ga), tungsten (W), iron (Fe), and tin (Sn) is able to become the insulating portion 130i.

A detailed description of the changes in the electrical properties of the active material layer 130 and the oxide semiconductor material due to doping of the first dopant will be described later.

According to an embodiment of the present disclosure, the channel portion 130n, the source connection portion 130a, and the drain connection portion 130b are regions that are not doped by the first dopant. The channel portion 130n, the source connection portion 130a, and the drain connection portion 130b are protected from the first dopant.

According to an embodiment of the present disclosure, an area having an electrical function among the active material layer 130 can be referred to as an active area ACT. In the thin film transistor 100 of FIGS. 1, 2, and 3, the active material layer 130 includes a channel portion 130n, a source connection portion 130a, a drain connection portion 130b, and an insulating portion 130i. In addition, in the thin film transistor 100 of FIGS. 1, 2, and 3, the channel portion 130n, the source connection portion 130a, and the drain connection portion 130b can be referred to as the active area ACT.

The channel portion 130n has semiconductor characteristics of the oxide semiconductor material constituting the active material layer 130. On the other hand, the source connection portion 130a and the drain connection portion 130b are conductive areas formed by selective conductorization.

The source connection portion 130a and the drain connection portion 130b can be formed by selectively conductorizing the active material layer 130. In detail, the source connection portion 130a and the drain connection portion 130b can be formed by selectively conductorizing the oxide semiconductor material constituting the active material layer 130. According to an embodiment of the present disclosure, selective conductorization is performed after forming the insulating portion 130i by selectively doping with the first dopant.

The selectively conductorized portion of the active material layer 130 has excellent electrical conductivity and can function as a wiring portion.

According to an embodiment of the present disclosure, the selective conductorization refers to improving a conductivity of a selected portion of the active material layer 130 or providing conductivity to the selected portion of the active material layer 130. According to an embodiment of the present disclosure, the selective conductorization can be achieved by doping a second dopant into a selected region of the active material layer 130. The source connection 130a and the drain connection portion 130b can contain a second dopant.

According to an embodiment of the present disclosure, doping can be performed by implanting dopant ions. In detail, the source connection portion 130a and the drain connection portion 130b can include a second dopant doped by ion implantation.

According to an embodiment of the present disclosure, the second dopant can include at least one of boron (B), phosphorus (P), fluorine (F), and hydrogen (H).

According to an embodiment of the present disclosure, the active material layer 130 is formed by an oxide semiconductor material, and a second dopant is implanted into selected portions of the active material layer 130 to form the source connection portion 130a and the drain connection portion 130b by doping.

However, an embodiment of the present disclosure is not limited thereto, and conductivity can be provided to the source connection portion 130a and the drain connection portion 130b by other methods. According to an embodiment of the present disclosure, conductivity can be provided to the source connection portion 130a and the drain connection portion 130b through plasma processing. For example, during the patterning process of the gate insulating layer 140 or the gate electrode 150, the source connection portion 130a and the drain connection portion 130b can be formed by selective conductorization through plasma processing.

When the source connection portion 130a and the drain connection portion 130b are doped with the first dopant, the electrical conductivity of the source connection portion 130a and the drain connection portion 130b can decrease. Therefore, in order to prevent the source connection portion 130a and the drain connection portion 130b from being doped by the first dopant during the manufacturing process of the thin film transistor 100, the source connection portion 130a and the drain connection portion 130b can be protected by a mask or the like.

The channel portion 130n is also protected from being doped by the first dopant. In addition, the channel portion 130n is protected from being doped by the second dopant.

According to an embodiment of the present disclosure, a region of the active material layer 130 that is not doped with the first dopant and the second dopant and is not conductorized can become the channel portion 130n.

The channel portion 130n of the active material layer 130 is a region that overlaps the gate electrode 150. A doping process for the second dopant can be performed using the gate electrode 150 as a mask. As a result, the portion of the active material layer 130 that overlaps the gate electrode 150 is not doped by the second dopant, and thus becomes a channel portion 130n.

On the other hand, the insulating portion 130i has stable insulation properties by doping with the first dopant. Accordingly, even though the insulating portion 130i is doped with the second dopant after the first dopant is doped, the insulating portion 130i can maintain insulating properties. Even if the insulating portion 130i is doped with a second dopant during the process of forming the source connection portion 130a and the drain connection portion 130b, the insulating property of the insulating portion 130i can be maintained.

According to an embodiment of the present disclosure, the insulating portion 130i can further include a second dopant.

According to an embodiment of the present disclosure, the channel portion 130n, the source connection portion 130a, the drain connection portion 130b, and the insulating portion 130i are distinguished from each other by dopant doping without patterning the active material layer 130. Alternatively, the channel portion 130n, the source connection portion 130a, the drain connection portion 130b, and the insulating portion 130i can be distinguished from each other by dopant doping and plasma processing without patterning the active material layer 130.

As such, according to an embodiment of the present disclosure, the active material layer 130 may not be patterned. In addition, the channel portion 130n, the source connection portion 130a, the drain connection portion 130b, and the insulating portion 130i can be integrally formed.

Referring to FIGS. 2 and 3, a gate insulating layer 140 is disposed on the active material layer 130. The gate insulating layer 140 can include at least one of silicon oxide, silicon nitride, and metal-based oxide. The gate insulating layer 140 can have a single-layer structure or a multi-layer structure. The gate insulating layer 140 protects the channel portion 130n.

Referring to FIGS. 1 and 2, the gate insulating layer 140 can be formed over the entire top surface of the base substrate 110. For example, the gate insulating layer 140 can cover all of the channel portion 130n, the source connection portion 130a, and the drain connection portion 130b, excluding the contact area.

However, an embodiment of the present disclosure is not limited thereto, and the gate insulating layer 140 can be patterned. For example, the gate insulating layer 140 can be patterned into a shape corresponding to the gate electrode 150.

The gate electrode 150 is disposed on the gate insulating layer 140. The gate electrode 150 is formed to overlap the channel portion 130n of the active material layer 130.

The gate electrode 150 can include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or molybdenum alloy, chromium (Cr), tantalum (Ta), neodymium (Nd), and titanium (Ti). The gate electrode 150 can have a multilayer structure including at least two conductive layers with different physical properties.

Referring to FIGS. 2 and 3, an interlayer insulating film 145 can be disposed on the gate insulating layer 140 and the gate electrode 150. The interlayer insulating film 145 is an insulating layer made of an insulating material. The interlayer insulating film 145 can be made of an organic material, an inorganic material, or a laminate of an organic material layer and an inorganic material layer.

The source electrode 160 and the drain electrode 170 can be disposed on the interlayer insulating film 145.

Each of the source electrode 160 and the drain electrode 170 can include at least one of molybdenum (Mo), aluminum (Al), chromium (Cr), gold (Au), titanium (Ti), nickel (Ni), neodymium (Nd), copper (Cu), and alloys thereof. Each of the source electrode 160 and the drain electrode 170 can be configured to be a single layer made of metal or a metal alloy, or a muli-layer made of two or more layers.

According to an embodiment of the present disclosure, the source electrode 160 can be connected to the source connection portion 130a. In detail, the source electrode 160 can be electrically connected to the source connection portion 130a through a contact hole and can transmit an electrical signal to the channel portion 130n.

The drain electrode 170 is spaced apart from the source electrode 160, and can be connected to the drain connection portion 130b. In detail, the drain electrode 170 can be electrically connected to the drain connection portion 130b through a contact hole and can transmit an electrical signal to the channel portion 130n.

According to an embodiment of the present disclosure, the source connection portion 130a can serve as a source electrode, and the drain connection portion 130b can serve as a drain electrode. In addition, the source connection portion 130a and the drain connection portion 130b can be interchanged with each other.

The source electrode 160 and drain electrode 170 can be omitted. When the source electrode 160 and the drain electrode 170 are omitted, the source connection portion 130a can serve as the source electrode and the drain connection portion 130b can serve as the drain electrode.

Hereinafter, changes in electrical characteristics of the active material layer 130 and the oxide semiconductor material due to doping with the first dopant will be described in detail.

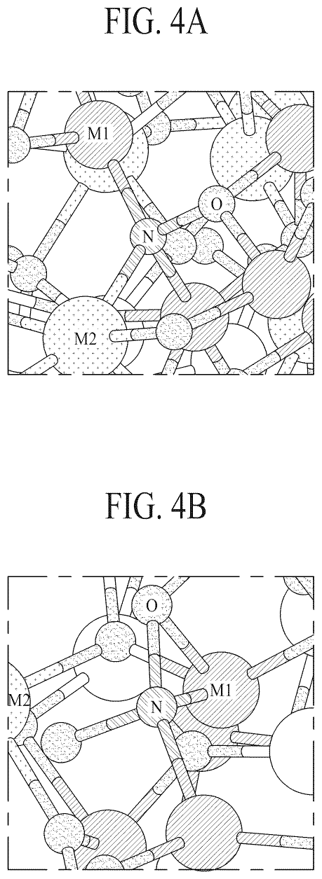

FIGS. 4A and 4B are diagrams illustrating bonding states of nitrogen (N) doped in an oxide semiconductor material constituting the active material layer 130, respectively.

In oxide semiconductor materials, oxygen vacancies occur when oxygen atoms bonded to metal atoms are removed. When an oxygen vacancy occurs, the free electrons bound by oxygen are released, and a carrier electron (e−) is generated. When nitrogen is doped into an oxide semiconductor material, the oxygen vacancy caused by the removal of an oxygen atom is filled by nitrogen (N). In detail, the site of oxygen vacancy generated by removal of an oxygen atom is filled with the doped nitrogen. When the site where the oxygen vacancy occurred is filled with nitrogen (N), the carrier electron (e−) is bound to nitrogen (N), and the carrier density and mobility of the oxide semiconductor material decrease. As a result, the resistance of the oxide semiconductor material can increase.

Referring to FIG. 4A, nitrogen (N) can be placed at the site where an oxygen vacancy occurred, and nitrogen (N) placed in the site can combine with other oxygen (O) present in the oxide semiconductor material, and can also be combined with other metal elements M1, M2.

Referring to FIG. 4B, nitrogen (N) doped into the oxide semiconductor material can combine with two oxygens to form an O—N—O bond. As a result, oxygen is prevented from escaping from the oxide semiconductor material, and the resistance of the oxide semiconductor material can further increase.

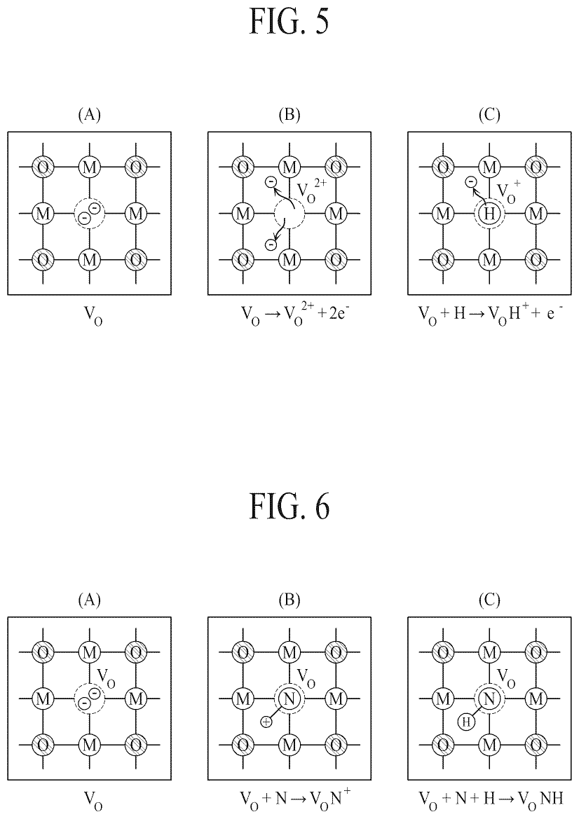

FIG. 5 is a schematic diagram illustrating oxygen vacancy Vo.

Referring to (A) of FIG. 5, two electrons (−) can be generated due to oxygen vacancy Vo. The valence of oxygen (O) is divalent (2+). Therefore, when an oxygen is removed from the oxide semiconductor material, as shown in (B) of FIG. 5, the effect is to remove a divalent oxygen atom (O²⁺), resulting to generate two electrons (−).

On the other hand, hydrogen has a mono-valent valance (1+) atom. Therefore, as shown in (C) of FIG. 5, when the oxygen vacancy (Vo) site is replaced with a hydrogen (H) atom, the effect is to place a hydrogen atom (H+) in a monovalent state, and thus one electron (−) is generated.

FIG. 6 is a schematic diagram illustrating a mechanism in which oxygen vacancies are removed by nitrogen (N) doping.

Referring to (A) of FIG. 6, two electrons (−) can be generated by oxygen vacancy Vo.

Nitrogen has a trivalent valence (3+). Therefore, as shown in (B) of FIG. 6, when nitrogen (N) is doped into the oxide semiconductor material, nitrogen (N) replaces the oxygen vacancy Vo site, and all of the two electrons (−) generated by the oxygen vacancy Vo can be trapped. Referring to (B) of FIG. 6, even after nitrogen (N) doped into the oxide semiconductor material has trapped all of the two electrons (−) generated by oxygen vacancy Vo, the nitrogen can still have one more site (labeled with a “+”) where it can trap an additional atom or electron.

Referring to (C) of FIG. 6, nitrogen (N) doped into the oxide semiconductor material not only replaces the oxygen vacancy Vo site, but also binds hydrogen (H) atom.

When hydrogen flows into the oxide semiconductor material, the hydrogen can combine with oxygen in the oxide semiconductor material and oxygen can be removed from the oxide semiconductor material. As a result, hydrogen can cause oxygen vacancy Vo in the oxide semiconductor material.

However, when nitrogen (N) is doped into an oxide semiconductor material, nitrogen (N) not only replaces the oxygen vacancy Vo site but also binds hydrogen (H) atom [see (C) of FIG. 6]. As a result, the occurrence of oxygen vacancy Vo due to hydrogen is prevented, and the insulating properties of the oxide semiconductor material can be stably maintained at the nitrogen doping site.

Therefore, the insulating portion 130i formed by nitrogen doping according to an embodiment of the present disclosure has excellent insulating properties and can stably maintain the insulating properties.

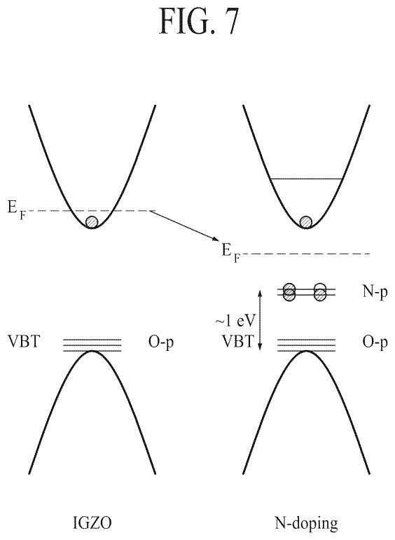

FIG. 7 is a schematic diagram illustrating a change in band gap state due to nitrogen-oxygen bonding (N—O bonding). In detail, FIG. 7 shows the valence band tail (VBT).

An oxide semiconductor material, for example, an IGZO-based oxide semiconductor material illustrated in FIG. 7 can have a valence band tail VBT due to the p orbital of the oxygen atom. When a nitrogen-oxygen (N—O) bond is formed by nitrogen doping (N-doping), an unfilled gap state in the band gap is formed by nitrogen with a p orbital (N-p) and oxygen with a p orbital (O-p), thus enabling electron trapping. In this way, the Fermi level Ef can be controlled by nitrogen doping, and the band gap can be increased to make the oxide semiconductor material insulating.

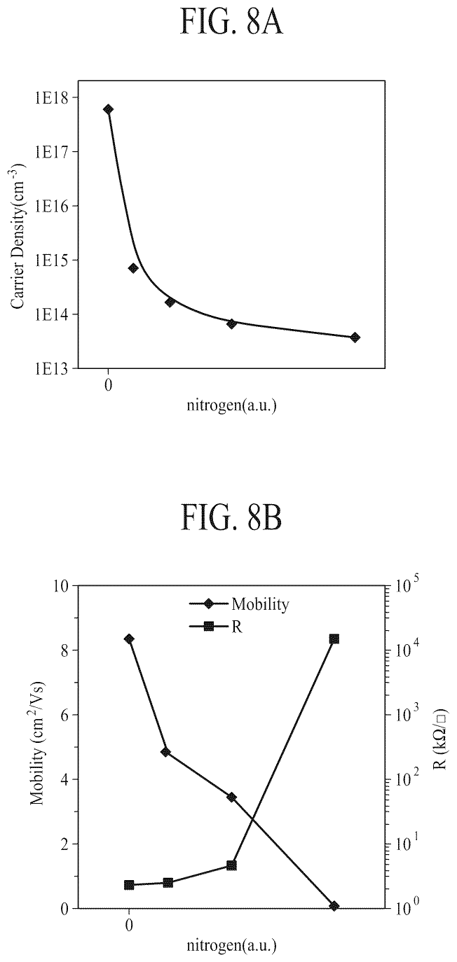

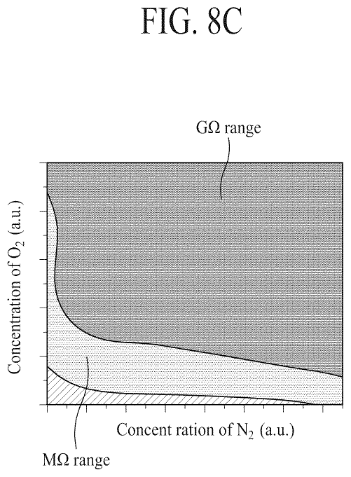

FIG. 8A is a graph illustrating a change in carrier density of an oxide semiconductor material depending on nitrogen (N) concentration, and FIG. 8B is a graph illustrating a change in mobility and surface resistance of an oxide semiconductor material depending on nitrogen (N) concentration. According to an embodiment of the present disclosure, the carrier density can be referred to as carrier concentration, and denotes the number of charge carriers per volume. For example, in an embodiment of the present disclosure, the carrier density is measured as number of charge carriers in cm⁻³.

Referring to FIG. 8A, it is noted that as the concentration of nitrogen (N) contained in the oxide semiconductor material increases, the carrier density of the oxide semiconductor material decreases.

Referring to FIG. 8B, it is noted that as the concentration of nitrogen (N) contained in the oxide semiconductor material increases, the mobility of the oxide semiconductor material decreases and the surface resistance (R) increases. According to an embodiment of the present disclosure, surface resistance (R) can be referred to as sheet resistance and denoted as “ohms per square” or “Ω/□”.

FIG. 8C illustrates the resistance of the oxide semiconductor material depending on the concentration of oxygen and nitrogen. In detail, FIG. 8C illustrates surface resistance of the oxide semiconductor layer as a function of the partial pressure of oxygen (O₂) and the amount of nitrogen (N₂) during the fabrication of the IGZO oxide semiconductor layer.

According to an embodiment of the present disclosure, in order for the insulating portion 130i to have sufficiently high resistivity and insulating properties, the oxygen content can be designed to be in a range of 40 to 60 atomic % (at %) and the nitrogen content can be designed to be in a range of 4 to 10 atomic % (at %) relative to the total number of atoms of the insulating portion 130i. Thus, the insulating portion 130i can include 40 to 60 atomic % (at %) of oxygen (O) and 4 to 10 atomic % (at %) of nitrogen (N), relative to the total number of atoms contained therein.

In more detail, in the insulating portion 130i, the oxygen content can be 50 atomic % (at %) or more, and the nitrogen content can be 4 atomic % (at %) or more relative to the total number of atoms included in the insulating portion 130i. In this case, the insulating portion 130i can contain more than 50 at % oxygen (O) and more than 4 at % nitrogen (N) relative to the total number of atoms included in the oxide semiconductor material.

Similar to nitrogen (N), at least one of sulfur(S) and chlorine (Cl), which are non-metallic elements, among the first dopants can also be doped into the oxide semiconductor material and placed at a site where an oxygen vacancy occurs. Since carriers generated by oxygen vacancies can be trapped by sulfur(S) or chlorine (Cl), the portion doped with the first dopant can have insulating properties. As a result, a portion of the active material layer 130 doped with at least one of sulfur(S) and chlorine (Cl) can become the insulating portion 130i.

When at least one of the first dopants, which are metal elements gallium (Ga), tungsten (W), iron (Fc), and tin (Sn), is doped into a portion of an oxide semiconductor material, the metal-oxygen bond in the doped portion can be increased. For example, in an oxygen atmosphere, which is under O₂ gas state, when an indium (In)-based oxide semiconductor material containing indium (In) is doped with metal elements such as gallium (Ga), tungsten (W), iron (Fe), and tin (Sn), the doped metal element replaces indium (In), and at the same time, the doped metal element can combine with oxygen (O). By this doping, indium (In) is removed from the doped region of the oxide semiconductor material, thereby lowering the carrier density, and doped metal elements can form strong bonds with oxygen. As a result, the portion of the oxide semiconductor material doped with metal elements such as gallium (Ga), tungsten (W), iron (Fe), and tin (Sn) becomes oxide, and the insulation of the doped portion can increase. Accordingly, the portion of the active material layer 130 doped with at least one of gallium (Ga), tungsten (W), iron (Fe), and tin (Sn) can be the insulating portion 130i.

The same metal element as the metal element included in the active area ACT of the active material layer 130 can be used as the first dopant. For example, the oxide semiconductor material constituting the active material layer 130 includes gallium (Ga), and gallium (Ga) can be used as the first dopant for forming the insulating portion 130i. In this case, the concentration of the gallium (Ga) in the insulating portion 130i is higher than the concentration of gallium (Ga) in the active area ACT. Therefore, according to an embodiment of the present disclosure, when the active area ACT includes the same element as the first dopant (hereinafter referred to as “dopant element”), the concentration of the dopant element included in the insulating portion 130i is higher than the concentration of the dopant element included in the active area ACT.

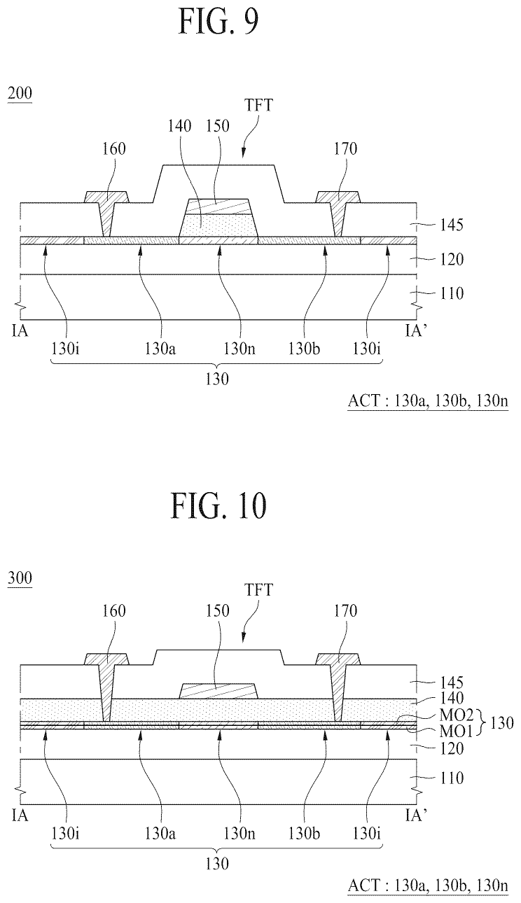

FIG. 9 is a cross-sectional view of a thin film transistor 200 according to another embodiment of the present disclosure. Hereinafter, in order to avoid redundancy, components that have already been described will be briefly described, or descriptions of components that have already been described will be omitted.

Referring to FIG. 9, the gate insulating layer 140 can be patterned. As shown in FIG. 9, the gate insulating layer 140 can be patterned into a shape corresponding to the gate electrode 150.

The gate insulating layer 140 and the gate electrode 150 can be patterned in one process. During the patterning process of the gate insulating layer 140 and the gate electrode 150, selective conductorization can be performed to form the source connection portion 130a and the drain connection portion 130b. In detail, during the patterning process of the gate insulating layer 140 and the gate electrode 150, selective conductorization can be performed in a plasma treatment process. resultingly, the source connection portion 130a and the drain connection portion 130b can be formed.

According to an embodiment of the present disclosure, the plasma treatment process is performed after forming the insulating portion 130i by selectively doping with the first dopant. Since the insulating portion 130i has stable insulating properties secured by doping with the first dopant, the insulating portion 130i is not conductorized and can maintain insulating properties even when exposed to the plasma treatment process.

FIG. 10 is a cross-sectional view of a thin film transistor 300 according to another embodiment of the present disclosure.

Referring to FIG. 10, the active material layer 130 can have a multilayer structure.

According to another embodiment of the present disclosure, the active material layer 130 can include a first oxide semiconductor material layer MO1 and a second oxide semiconductor material layer MO2 on the first oxide semiconductor material layer MO1. The first oxide semiconductor material layer MO1 and the second oxide semiconductor material layer MO2 can include the same semiconductor material or different semiconductor materials.

The first oxide semiconductor material layer MO1 supports the second oxide semiconductor material layer MO2. Therefore, the first oxide semiconductor material layer MO1 can be called a support layer. The main channel portion can be formed in the second oxide semiconductor material layer MO2. However, an embodiment of the present disclosure is not limited thereto, and the main channel portion can be formed in the first oxide semiconductor material layer MO1.

FIG. 11 is a cross-sectional view of a thin film transistor 400 according to another embodiment of the present disclosure.

The thin film transistor 400 according to another embodiment of the present disclosure can further include a light shielding layer 111 that overlaps the channel portion 130n.

The light shielding layer 111 is disposed between the base substrate 110 and the active material layer 130. In detail, the light shielding layer 111 can be disposed between the base substrate 110 and the buffer layer 120.

The light shielding layer 111 blocks light incident from the outside, and protects channel portion 130n. The light shielding layer 111 can be made of a material with light blocking properties. The light shielding layer 111 can include at least one of aluminum-based metals such as aluminum (Al) or aluminum alloys, molybdenum-based metals such as molybdenum (Mo) or molybdenum alloys, chromium (Cr), tantalum (Ta), neodymium (Nd), titanium (Ti), and iron (Fe).

According to an embodiment of the present disclosure, light shielding layer 111 can have electric conductivity. The light shielding layer 111 can be electrically connected to either the source electrode 160 or the drain electrode 170.

Referring to FIG. 11, the light shielding layer 111 is connected to the source connection portion 130a. The light shielding layer 111 can be electrically connected to the source electrode 160 through the source connection portion 130a. However, an embodiment of the present disclosure is not limited thereto, and the light shielding layer 111 can be connected to the drain connection portion 130b. The light shielding layer 111 can be electrically connected to the drain electrode 170 through the drain connection portion 130b.

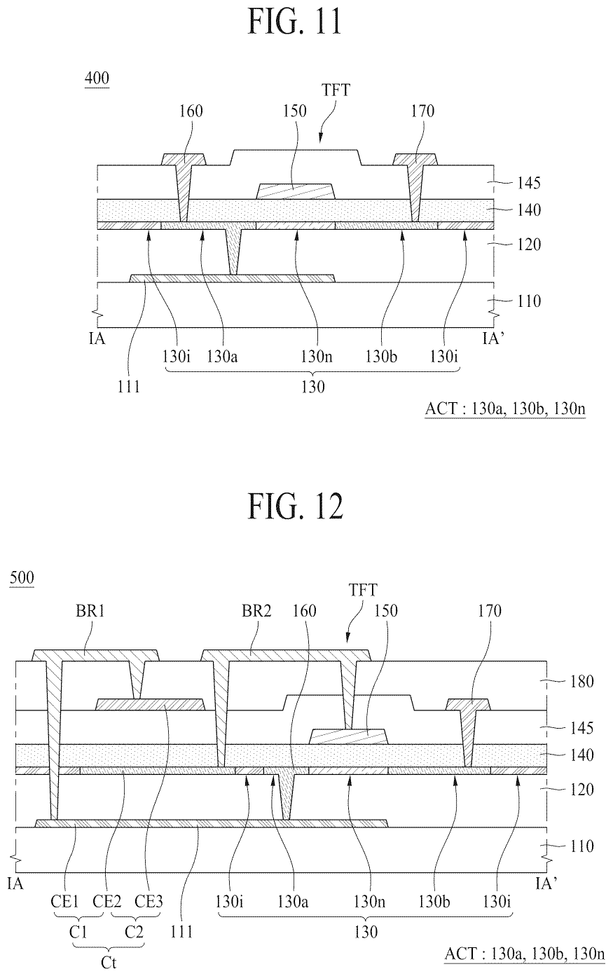

FIG. 12 is a cross-sectional view of a thin film transistor 500 according to another embodiment of the present disclosure.

According to another embodiment of the present disclosure, the light shielding layer 111 of the thin film transistor 500 can serve as a capacitor electrode. In detail, the thin film transistor 500 according to another embodiment of the present disclosure can further include a first capacitor electrode CE1, which is integrated with the light shielding layer 111 and does not overlap the channel portion 130n. The first capacitor electrode CE1 can be connected to the light shielding layer 111. Referring to FIG. 12, a portion of the light shielding layer 111 that does not overlap the channel portion 130n can serve as the first capacitor electrode CE1.

A structure in which the light shielding layer 111 is electrically connected to the source electrode 160 through the source connection portion 130a is illustrated in FIG. 12. In FIG. 12, the source connection portion 130a is the source electrode 160. By this connection, the first capacitor electrode CE1 can be connected to the source electrode 160 through the source connection portion 130a. Referring to FIG. 12, the first capacitor electrode CE1 is connected to the light shielding layer 111, and thus the first capacitor electrode CE1 can be applied with a same voltage as the voltage applied to the source electrode 160.

In the thin film transistor 500 illustrated in FIG. 12, the source connection portion 130a serves as the source electrode 160.

According to another embodiment of the present disclosure, the thin film transistor 500 can include a second capacitor electrode CE2. Referring to FIG. 12, the second capacitor electrode CE2 can be formed in the active material layer 130. For example, a portion of the active material layer 130 can be conductorized to become the second capacitor electrode CE2.

In detail, the active material layer 130 can include a second capacitor electrode CE2 spaced apart from the channel portion 130n. The second capacitor electrode CE2 can be insulated from at least one of the source connection portion 130a and the drain connection portion 130b by the insulating portion 130i. Referring to FIG. 12, the second capacitor electrode CE2 is spaced apart from and insulated from the source connection portion 130a with the insulating portion 130i interposed therebetween. In addition, the second capacitor electrode CE2 is spaced apart from and insulated from the drain connection portion 130b.

According to another embodiment of the present disclosure, the first capacitor electrode CE1 and the second capacitor electrode CE2 can overlap each other to form the first capacitor C1.

Referring to FIG. 12, the thin film transistor 500 can include a third capacitor electrode CE3. The third capacitor electrode CE3 can be disposed on the interlayer insulating film 145.

The third capacitor electrode CE3 can overlap the second capacitor electrode CE2. The second capacitor electrode CE2 and the third capacitor electrode CE3 can overlap each other to form the second capacitor C2. A total capacitor Ct can be formed by the first capacitor C1 and the second capacitor C2.

A passivation layer 180 can be disposed on the drain electrode 170 and the third capacitor electrode CE3. A bridge electrode BR1, BR2 can be disposed on the passivation layer 180.

The third capacitor electrode CE3 can be connected to the first capacitor electrode CE1 through a bridge electrode BR1. With this connection, a same voltage can be applied to the first capacitor electrode CE1 and the third capacitor electrode CE3. In the thin film transistor 500 illustrated in FIG. 12, the third capacitor electrode CE3 can be subjected to the same voltage as the voltage applied to the source electrode 160.

The second capacitor electrode CE2 can be connected to the gate electrode 150 through another bridge electrode BR2. This connection allows the second capacitor electrode CE2 to be subjected to the same voltage as the gate electrode 150.

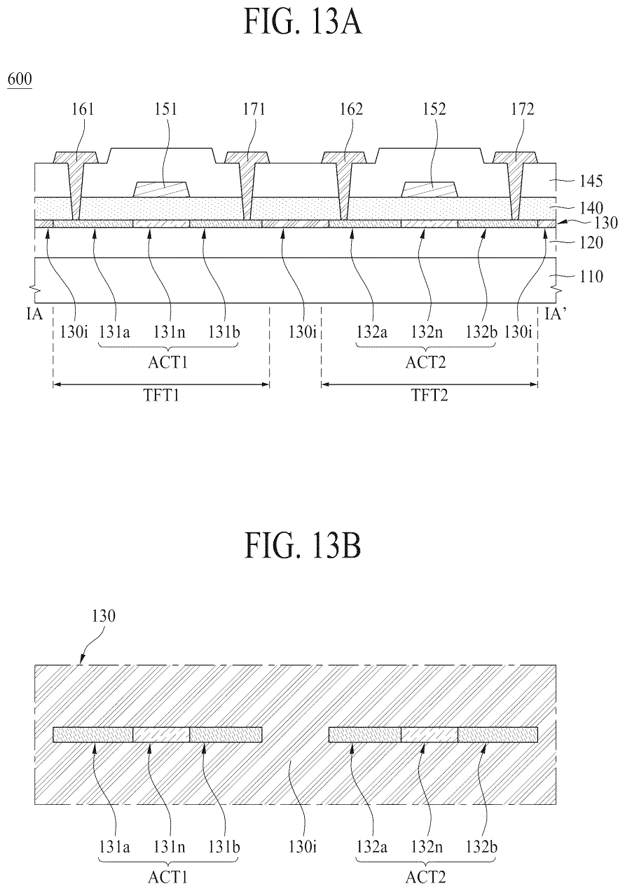

FIG. 13A is a cross-sectional view of a thin film transistor substrate 600 according to another embodiment of the present disclosure.

Particularly, FIG. 13A shows a structure in which two thin film transistors TFT1, TFT2 are formed by one active material layer 130.

Referring to FIG. 13A, a thin film transistor substrate 600 according to another embodiment of the present disclosure includes a first thin film transistor TFT1 and a second thin film transistor TFT2 on a base substrate 110, and the first thin film transistor TFT1 and the second thin film transistor TFT2 include an active material layer 130.

In detail, the first thin film transistor TFT1 includes a first channel portion 13 In on the base substrate 110, a first source connection portion 131a connected to one side of the first channel portion 131n, a first drain connection portion 131b connected to the other side of the first channel portion 131n, and a first gate electrode 151 spaced apart from the active material layer 130 and overlapping the first channel portion 131n. According to another embodiment of the present disclosure, the first channel portion 131n, the first source connection portion 131a, and the first drain connection portion 131b can be referred to as the first active area ACT1. The first thin film transistor TFT1 can include a first source electrode 161 and a first drain electrode 171 disposed on the interlayer insulating film 145.

The second thin film transistor TFT2 includes a second channel portion 132n on the base substrate 110, a second source connection portion 132a connected to one side of the second channel portion 132n, a second drain connection portion 132b connected to the other side of the second channel portion 132n, and a second gate electrode 152 spaced apart from the active material layer 130 and overlapping the second channel portion 132n. According to another embodiment of the present disclosure, the second channel portion 132n, the second source connection portion 132a, and the second drain connection portion 132b can be referred to as the second active area ACT2. The second thin film transistor TFT2 can include a second source electrode 162 and a second drain electrode 172 disposed on the interlayer insulating film 145.

The active material layer 130 includes a first channel portion 131n, a first source connection portion 131a, a first drain connection portion 131b, a second channel portion 132n, a second source connection portion 132a, a second drain connection portion 132b and an insulating portion 130i. The first channel portion 131n, the first source connection portion 131a, the first drain connection portion 131b, the second channel portion 132n, the second source connection portion 132a, the second drain connection portion 132b, and the insulating portion 130i can be disposed on a same layer.

According to another embodiment of the present disclosure, the first channel portion 131n, the first source connection portion 131a, the first drain connection portion 131b, the second channel portion 132n, the second source connection portion 132a, the second drain connection portion 132b, and the insulating portion 130i included in the active material layer 130 can all be disposed on the buffer layer 120.

According to another embodiment of the present disclosure, the active material layer 130 can be configured to have a single structure that is not patterned. Accordingly, the first channel portion 131n, the first source connection portion 131a, the first drain connection portion 131b, the second channel portion 132n, the second source connection portion 132a, the second drain connection portion 132b, and the insulating portion 130i can be integrally formed.

FIG. 13B is a plan view of the active material layer 130 of FIG. 13A.

Referring to FIG. 13B, the active material layer 130 can have one integrated structure including the first channel portion 131n, the first source connection portion 131a, the first drain connection portion 131b, the second channel portion 132n, the second source connection portion 132a, the second drain portion and the insulating portion 130i.

In FIG. 13B, a region of the active material layer 130 other than the first active area ACT1 and the second active area ACT2 can be the insulating portion 130i. In FIG. 13B, an active material layer 130 is illustrated in which all areas excluding the first channel portion 131n, the first source connection portion 131a, the first drain connection portion 131b, the second channel portion 132n, the second source connection portion 132a, and the second drain connection portion 132b are the insulating portions 130i. However, an embodiment of the present disclosure is not limited thereto, and the active material layer 130 can further include a capacitor electrode, a wiring portion, or the like.

According to another embodiment of the present disclosure, the first thin film transistor TFT1 and the second thin film transistor TFT2 can be spaced apart from each other with an insulating portion 130i therebetween. The insulating portion 130i can serve as an insulator that electrically separates components each other.

In addition, at least one of the first source connection portion 131a and the first drain connection portion 131b is insulated from at least one of the second source connection portion 132a and the second drain connection portion 132b by the insulating portion 130i.

The active material layer 130 can include an oxide semiconductor material. In detail, the first channel portion 131n, the first source connection portion 131a, the first drain connection portion 131b, the second channel portion 132n, the second source connection portion 132a, the second drain connection portion 132b, and the insulating portion 130i can include an oxide semiconductor material.

The insulating portion 130i further includes a first dopant. The first dopant can include at least one of nitrogen (N), sulfur(S), chlorine (Cl), gallium (Ga), tungsten (W), iron (Fe), and tin (Sn). By doped with the first dopant, a specific portion of the active material layer 130 including an oxide semiconductor material can selectively have insulating properties. Since the first dopant and dopant doping have already been described, detailed description thereof will be omitted.

The first source connection portion 131a, the first drain connection portion 131b, the second source connection portion 132a, and the second drain connection portion 132b can include a second dopant. The second dopant is different from the first dopant. The second dopant can include at least one of boron (B), phosphorus (P), fluorine (F), and hydrogen (H).

The second dopant can have a opposite function to the first dopant. By doping with the second dopant, a portion of the active material layer 130 including an oxide semiconductor material can be selectively conductorized. During the conductorization process using the second dopant, the insulating portion 130i can be doped with the second dopant. As a result, the insulating portion 130i can further include the second dopant. Since the second dopant and conductorization have already been described, detailed description thereof will be omitted.

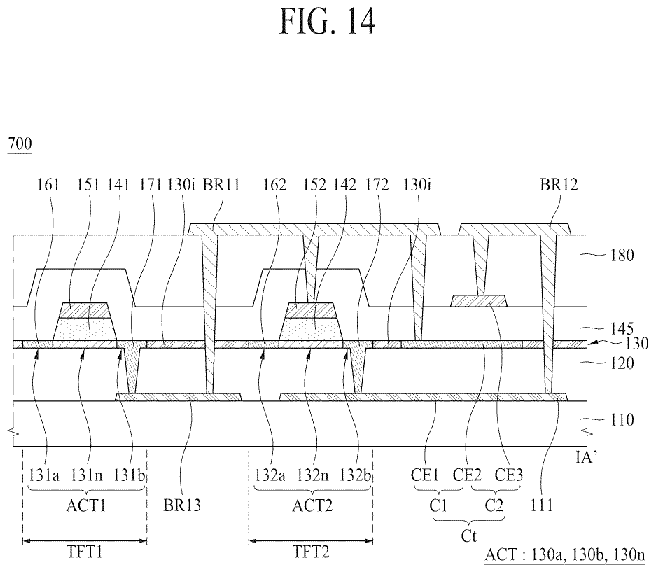

FIG. 14 is a cross-sectional view of a thin film transistor substrate 700 according to another embodiment of the present disclosure.

Referring to FIG. 14, the thin film transistor TFT1, TFT2 can be connected to a capacitor Ct.

The thin film transistor substrate 700 illustrated in FIG. 14 includes a light shielding layer 111 and a bridge electrode BR13 disposed on the base substrate 110. The light shielding layer 111 overlaps the second channel portion 132n of the second thin film transistor TFT2.

According to another embodiment of the present disclosure, the thin film transistor substrate 700 can include a first capacitor electrode CE1. The first capacitor electrode CE1 can be formed integrally with the light shielding layer 111 and does not overlap the second channel portion 132n. Referring to FIG. 14, a portion of the light shielding layer 111 that does not overlap the second channel portion 132n can be the first capacitor electrode CE1.

The light shielding layer 111 can be connected to the second drain connection portion 132b of the second thin film transistor TFT2. Because the first capacitor electrode CE1 is connected to the light shielding layer 111, a voltage same with the voltage applied to the second drain connection portion 132b can be applied to the first capacitor electrode CE1.

In the thin film transistor substrate 700 illustrated in FIG. 14, the second drain connection portion 132b can serve as the second drain electrode 172, and the second source connection portion 132a can serve as the second source electrode 162.

According to another embodiment of the present disclosure, the thin film transistor substrate 700 can include a second capacitor electrode CE2. The second capacitor electrode CE2 can be formed in the active material layer 130. For example, a portion of the active material layer 130 can be conductorized to become the second capacitor electrode CE2.

The active material layer 130 can include a second capacitor electrode CE2 spaced apart from the second channel portion 132n. The second capacitor electrode CE2 can be insulated from the second drain connection portion 132b by the insulating portion 130i. The first capacitor electrode CE1 and the second capacitor electrode CE2 overlap each other to form the first capacitor C1.

The thin film transistor substrate 700 can further include a third capacitor electrode CE3. The third capacitor electrode CE3 can overlap the second capacitor electrode CE2. The second capacitor electrode CE2 and the third capacitor electrode CE3 overlap each other to form the second capacitor C2. A capacitor Ct, which is a total capacitor, can be formed by the first capacitor C1 and the second capacitor C2.

The third capacitor electrode CE3 can be connected to the first capacitor electrode CE1 through the bridge electrode BR12. Through this connection, a same voltage can be applied to the first capacitor electrode CE1 and the third capacitor electrode CE3. In the thin film transistor substrate 700 illustrated in FIG. 14, a same voltage as the voltage of second drain connection portion 132b can be applied to the third capacitor electrode CE3.

The second capacitor electrode CE2 can be connected to the second gate electrode 152 of the second thin film transistor TFT2, through a bridge electrode BR11. With this connection, a same voltage as the voltage applied to the second gate electrode 152 can be applied to the second capacitor electrode CE2.

In addition, the second gate electrode 152 of the second thin film transistor TFT2 can be connected to the first drain connection portion 131b of the first thin film transistor TFT1 through a bridge electrode BR13. As a result, a same voltage can be applied to the first drain connection portion 131b of the first thin film transistor TFT1, the second gate electrode 152 of the second thin film transistor TFT2, and the second capacitor electrode CE2. In addition, a signal transmitted to the first drain connection portion 131b passing through the first thin film transistor TFT1 can be applied to the second gate electrode 152 of the second thin film transistor TFT2.

The gate insulating layer 141, 142 can be patterned. The first gate electrode 151 is disposed on the first gate insulating film 141 of the first thin film transistor TFT1, and the second gate electrode 152 can be disposed on the second gate insulating film 142 of the second thin film transistor TFT2. In the thin film transistor substrate 700 illustrated in FIG. 14 the first drain connection portion 131b can serve as the first drain electrode 171, and the first source connection portion 131a can serve as the first source electrode 161.

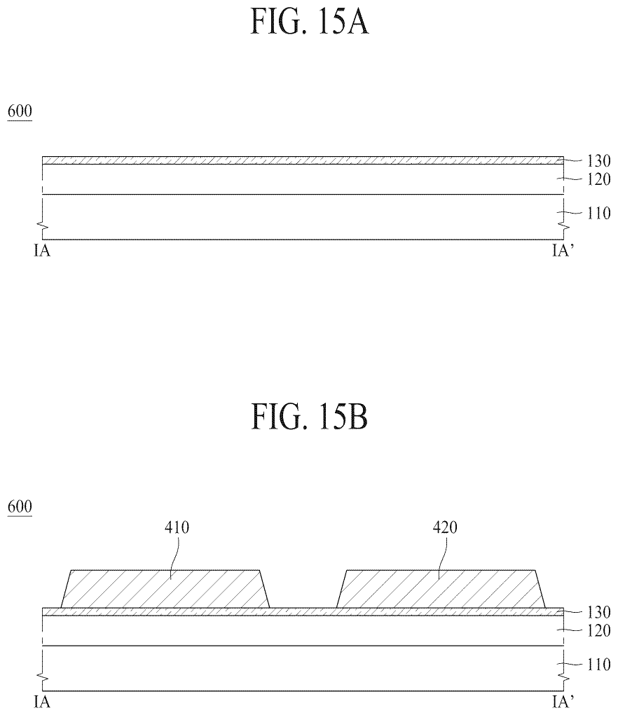

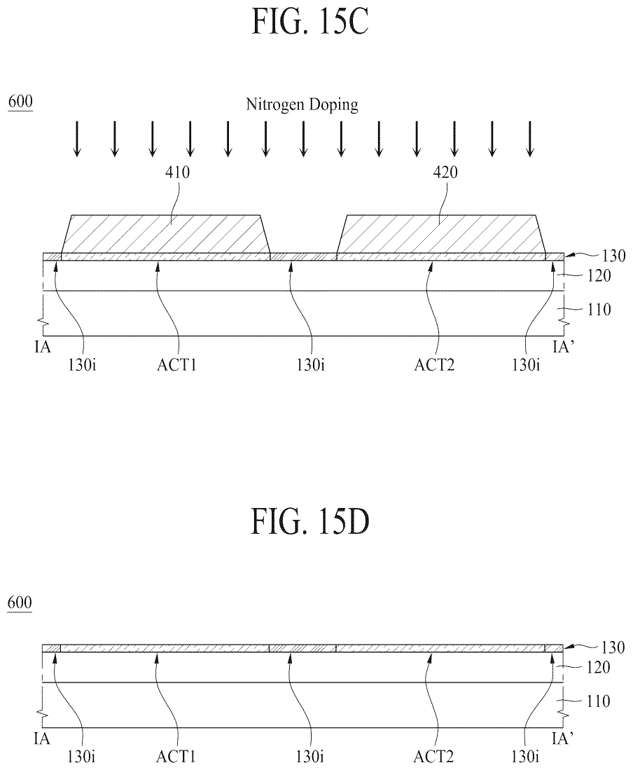

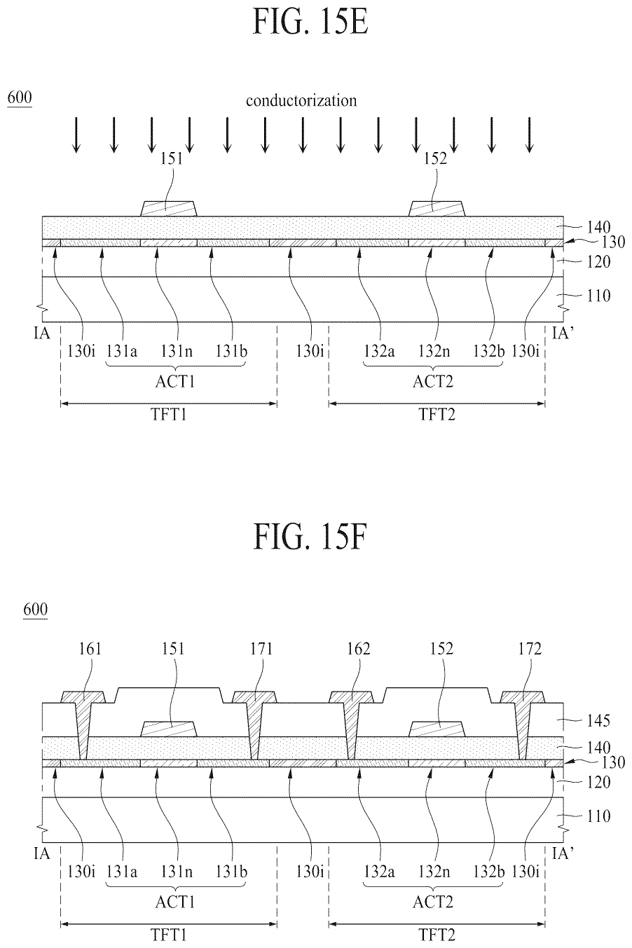

Hereinafter, a method of manufacturing a thin film transistor substrate 600 according to another embodiment of the present disclosure will be described with reference to the FIGS. 15A to 15F. The manufacturing method illustrated in FIGS. 15A to 15F can also be applied to thin film transistors 100, 200, 300, 400, and 500 according to embodiments of the present disclosure. Accordingly, the method of manufacturing the thin film transistor substrate 600 illustrated in FIGS. 15A to 15F can be referred to as method of manufacturing a thin film transistor.

FIGS. 15A to 15F are cross-sectional views illustrating a manufacturing process of a thin film transistor substrate 600 according to another embodiment of the present disclosure.

Referring to FIG. 15A, in order to manufacture the thin film transistor substrate 600 or a thin film transistor, an active material layer 130 is formed on a base substrate 110. In detail, as shown in FIG. 15A, a buffer layer 120 can be formed on the base substrate 110, and an active material layer 130 can be formed on the buffer layer 120. A light shielding layer 111 can be further formed between the base substrate 110 and the buffer layer 120.

Referring to FIG. 15B, a mask 410, 420 is formed on the active material layer 130. According to another embodiment of the present disclosure, masks 410 and 420 can be formed by photoresist. The photoresist pattern formed by exposure and development of photoresist can become the mask 410, 420.

The mask 410, 420 is formed in an area overlapping an active areas ACT1, ACT2. For example, a first mask 410 is formed on an area overlapping the first active area ACT1 of the first thin film transistor TFT1, and a second mask 420 can be formed on an area overlapping the second active area ACT2 of the second thin film transistor TFT2.

Referring to FIG. 15C, doping is performed to form an insulating portion 130i. In detail, a region of the active material layer 130 that does not overlap the mask 410, 420 is doped with the first dopant to form the insulating portion 130i.

According to another embodiment of the present disclosure, the first dopant can include at least one of nitrogen (N), sulfur(S), chlorine (Cl), gallium (Ga), tungsten (W), iron (Fe), and tin (Sn). Referring to FIG. 15C, an insulating portion 130i can be formed, for example, by nitrogen doping. A region of the active material layer 130 overlapping the mask 410, 420 is not doped by the first dopant.

The regions of the active material layer 130 that overlap the mask 410, 420 are not doped, to form a first active area ACT1 of the first thin film transistor TFT1 and a second active region ACT2 of the second thin film transistor TFT2.

Referring to FIG. 15D, mask 410, 420 is removed. Accordingly, the active material layer 130 is formed including active region ACT1, ACT2.

Referring to FIG. 15E, a gate insulating layer 140 is formed on the active material layer 130, and gate electrode 151, 152 is formed on the gate insulating layer 140. The gate electrode 151, 152 is formed on the active material layer 130 to be spaced apart from the active material layer 130. In detail, the first gate electrode 151 is formed to at least partially overlap the first active area ACT1 of the first thin film transistor TFT1, and the second gate electrode 152 is formed to at least partially overlap the second active area ACT2 of the second thin film transistor TFT2.

Next, a conductorization process is performed. Regions of the active material layer 130 that do not overlap the gate electrode 151, 152 are conductorized by the conductorization process, thereby forming source connection portions 131a, 132a and drain connection portions 131b, 132b. Among the active area ACT1, ACT2, the region that overlap the gate electrode 151, 152 is not conductorized and becomes channel portion 131n, 132n.

In detail, by the conductorization process, regions of the first active area ACT1 that do not overlap the first gate electrode 151 are conductorized to form the first source connection portion 131a and the first drain connection portion 131b. In addition, regions of the second active area ACT2 that do not overlap the second gate electrode 152 are conductorized to form the second source connection portion 132a and the second drain connection portion 132b.

A portion of the first active area ACT1 overlapping the first gate electrode 151 becomes the first channel portion 131n. A portion of the second active area ACT2 overlapping the second gate electrode 152 becomes the second channel portion 132n.

The source connection portion 131a, 132a is disposed between the channel portion 131n, 132n and the insulating portion 130i. The drain connection portion 131b, 132b is spaced apart from the source connection portion 131a, 132a and disposed between the channel portion 131n, 132n and the insulating portion 130i.

Conductorization can be achieved by plasma treatment or doping with a second dopant. According to another embodiment of the present disclosure, the second dopant can be different from the first dopant.

When conductorization is achieved by doping with the second dopant, at least one of boron (B), phosphorus (P), fluorine (F), and hydrogen (H) can be used as the second dopant.

Next, referring to FIG. 15F, an interlayer insulating film 145 is formed on the gate electrode 151, 152 and source electrode 161, 162 and drain electrode 171, 172 are formed on the interlayer insulating film 145, to complete the first thin film transistor TFT1 and the second thin film transistor TFT2. As a result, a thin film transistor according to an embodiment of the present disclosure can be manufactured, and a thin film transistor substrate 600 according to another embodiment of the present disclosure can be manufactured.

Hereinafter, a display apparatus including the thin film transistor or thin film transistor substrate described above will be described in detail.

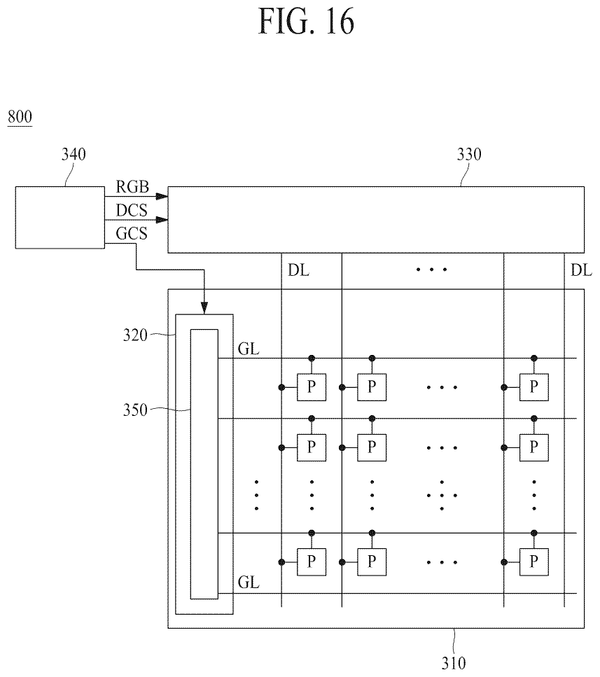

FIG. 16 is a schematic diagram of a display apparatus 800 according to another embodiment of the present disclosure.

Referring to FIG. 16, the display apparatus 800 according to another embodiment of the present disclosure can include a display panel 310, a gate driver 320, a data driver 330, and a controller 340.

Gate lines GL and data lines DL are placed in the display panel 310, and pixels P are disposed at intersections of the gate lines GL and data lines DL. Images are displayed by driving pixels P.

The controller 340 controls the gate driver 320 and data driver 330.

The controller 340 uses, for example, a signal supplied from an external system to generate a gate control signal GCS to control the gate driver 320 and a data control signal DCS to control the data driver 330. In addition, the controller 340 samples input image data input from an external system, realigns it, and supplies the realigned digital image data RGB to the data driver 330.

The gate control signal GCS includes a gate start pulse GSP, gate shift clock GSC, gate output enable signal GOE, start signal Vst, and gate clock GCLK. In addition, the gate control signal GCS can include control signals for controlling the shift register 350.

The data control signal DCS includes a source start pulse SSP, source shift clock signal SSC, source output enable signal SOE, and polarity control signal POL.

The data driver 330 supplies data voltage to the data lines DL of the display panel 310. In detail, the data driver 330 converts the image data RGB input from the controller 340 into an analog data voltage and supplies the data voltage to the data lines DL.

The gate driver 320 can include a shift register 350. The shift register 350 sequentially supplies gate pulses to the gate lines GL for one frame using a start signal and gate clock transmitted from the controller 340.

Using the shift register 350, the gate driver 320 can sequentially supply gate pulses GP to the gate lines GL during one frame. Here, one frame refers to the period during which one image is output through the display panel. In addition, the gate driver 320 supplies a gate off signal Goff that can turn off the switching element to the gate line GL during the remaining period in one frame in which the gate pulse GP is not supplied. Hereinafter, the gate pulse GP and the gate off signal Goff are collectively referred to as the scan signal SS.

According to an embodiment of the present disclosure, the gate driver 320 can be mounted in the display panel 310. In this way, the structure in which the gate driver 320 is directly mounted in the display panel 310 is called a gate in panel (GIP) structure.

The display panel 310 can include a plurality of pixels P. A plurality of pixels P can be disposed on the base substrate 110. Each of the plurality of pixels P can include a pixel driving circuit PDC. A plurality of pixel driving circuits PDC corresponding to the plurality of pixels P can be disposed on the base substrate 110.

Each of the plurality of pixel driving circuits PDC can include the thin film transistor TFT described above. In addition, each of the plurality of pixel driving circuits PDC can include the first thin film transistor TFT1 and the second thin film transistor TFT2 described above. Each of the thin film transistors TFT, TFT1, TFT2 included in the pixel driving circuit PDC include an active material layer 130, and the active material layer 130 can be formed integrally throughout the plurality of pixels P.

According to an embodiment of the present disclosure, the active material layer 130 can be formed integrally without being patterned in each of the plurality of pixels P. In addition, the active material layer 130 can be formed integrally between the plurality of pixels P. In detail, the active material layer 130 can be formed integrally between the plurality of pixels P without being patterned.

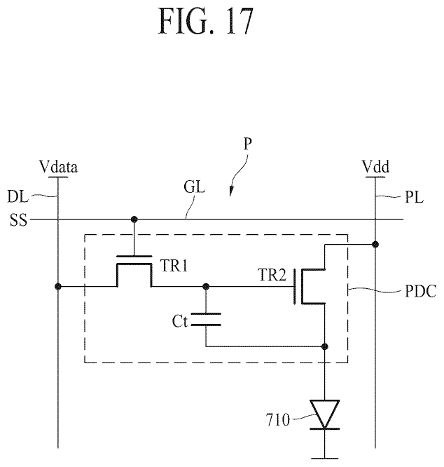

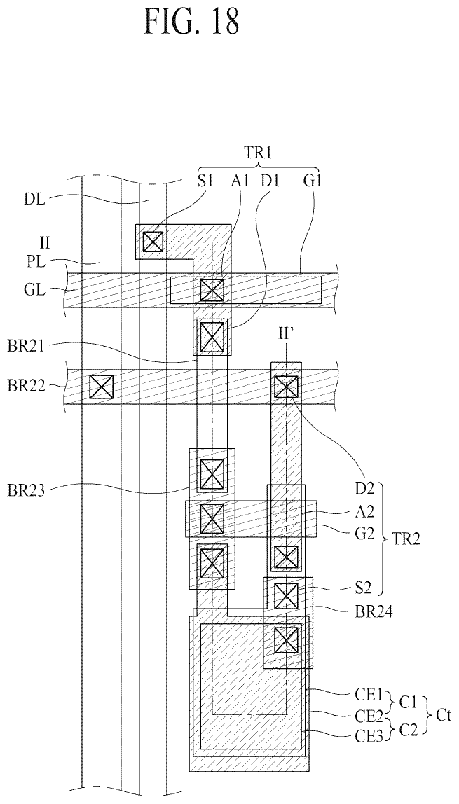

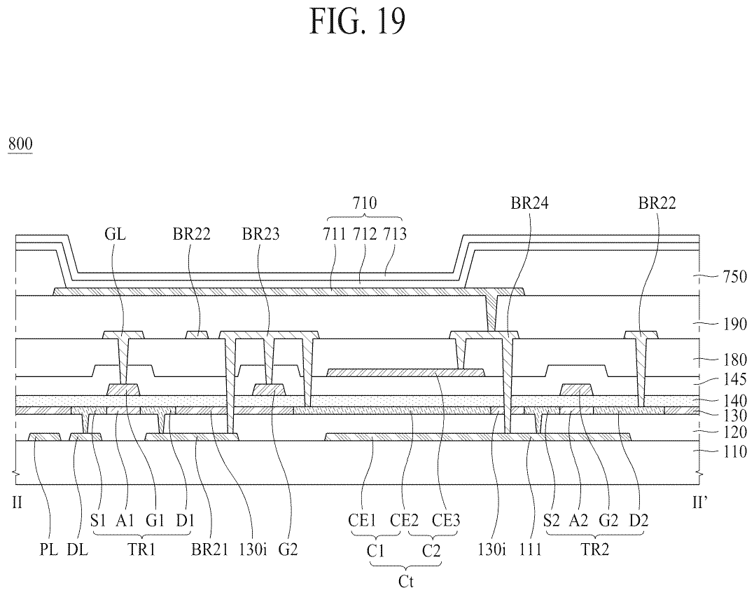

FIG. 17 is a circuit diagram of a pixel P of FIG. 16, FIG. 18 is a plan view of the pixel P of FIG. 17, and FIG. 19 is a cross-sectional view along II-II′ of FIG. 18.

The circuit diagram of FIG. 17 is an equivalent circuit diagram of a pixel P of the display apparatus 800 including an organic light emitting diode OLED as a display element 710.

The pixel P includes a display element 710 and a pixel driving circuit PDC that drives the display element 710.

The first thin film transistor TR1 is connected to the gate line GL and the data line DL, and is turned on or turned off by the scan signal SS supplied through the gate line GL. As the first thin film transistor TR1 of FIG. 17, the thin film transistor TFT or the first thin film transistor TFT1 described above can be applied.

The data line DL provides a data voltage Vdata to the pixel driving circuit PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode OLED, which is the display element 710. As the second thin film transistor TR2 of FIG. 17, the thin film transistor TFT or the second thin film transistor TFT2 described above can be applied.

When the first thin film transistor TR1 is turned on by the scan signal SS applied from the gate driver 320 through the gate line GL, the data voltage Vdata supplied from the data line DL is supplied to the gate electrode of the second thin film transistor TR2 connected to the display element 710. The data voltage Vdata is charged in the capacitor Ct formed between the gate electrode and the source electrode of the second thin film transistor TR2. The capacitor Ct of FIG. 17 is a storage capacitor.

The amount of current supplied to the organic light emitting diode OLED, which is the display element 710, through the second thin film transistor TR2 is controlled according to the data voltage Vdata, whereby a gray scale of light emitted from the display element 710 can be controlled.

Referring to FIGS. 18 and 19, the first thin film transistor TR1 and the second thin film transistor TR2 are disposed on the base substrate 110.

The base substrate 110 can be made of glass or plastic. As the base substrate 110, a plastic with flexible properties, for example, polyimide PI, can be used.

A light shielding layer 111 is disposed on the base substrate 110. The light shielding layer 111 can have light blocking properties. The light shielding layer 111 can protect the active material layer and channel portion A2 by blocking light incident from the outside. A portion of the light shielding layer 111 can become a first capacitor electrode CE1. Referring to FIGS. 18 and 19, the light shielding layer 111 and the first capacitor electrode CE1 can be formed integrally.

In addition, a data line DL, a driving power line PL, and a first bridge electrode BR21 can be disposed on the base substrate 110.

A buffer layer 120 is disposed on the light shielding layer 111, the first capacitor electrode CE1, the data line DL, the driving power line PL, and the first bridge electrode BR21. The buffer layer 120 can be made of an insulating material and protects the channel portions A1 and A2 from moisture or oxygen entering from the outside.

The active material layer 130 is disposed on the buffer layer 120. The active material layer 130 can include an oxide semiconductor material. The active material layer 130 can include an oxide semiconductor layer made of an oxide semiconductor material.

The active material layer 130 includes a first channel portion A1, a first source connection portion, a first drain connection portion, a second channel portion A2, a second source connection portion, a second drain connection portion, and an insulating portion 130i. Referring to FIGS. 18 and 19, the first source connection portion becomes the first source electrode S1, the first drain connection portion becomes the first drain electrode D1, the second source connection portion becomes the second source electrode S2, and the second drain connection portion becomes the second drain electrode D2.

In addition, a portion of the active material layer 130 can be conductorized to become a second capacitor electrode CE2. In another embodiment of the present disclosure, a drain region of the first thin film transistor TR1 can be extended to become the second capacitor electrode CE2.

According to an embodiment of the present disclosure, the active material layer 130 can be formed integrally within each pixel P without being patterned. In addition, the plurality of active material layers 130 can be formed integrally between pixels P without being patterned.

The first source electrode S1 of the first thin film transistor TR1 is connected to the data line DL through a contact hole. The first drain electrode D1 of the first thin film transistor TR1 is connected to the first bridge electrode BR21 through a contact hole.

The second source electrode S2 of the second thin film transistor TR2 is connected to the light shielding layer 111 through a contact hole. Accordingly, a same voltage as the voltage of the second source electrode S2 can be applied to the first capacitor electrode CE1.

A gate insulating layer 140 is disposed on the active material layer 130. The gate insulating layer 140 has insulating properties and separates the active material layer 130 from the gate electrode G1, G2. The gate insulating layer 140 can cover the entire top surface of the active material layer 130.

A first gate electrode G1 of the first thin film transistor TR1 and A second gate electrode G2 of the second thin film transistor TR2 are disposed on the gate insulating layer 140.

Referring to FIGS. 18 and 19, an interlayer insulating film 145 is disposed on the gate electrode G1, G2, and a third capacitor electrode CE3 is disposed on the interlayer insulating film 145. The third capacitor electrode CE3 can be disposed to overlap the first capacitor electrode CE1 and the second capacitor electrode CE2.

A passivation layer 180 can be disposed on the third capacitor electrode CE3. The passivation layer 180 protects the thin film transistor TR1, TR2.

A gate line GL and bridge electrode BR22, BR23, BR24 are disposed on the passivation layer 180.

The gate line GL is connected to the first gate electrode G1 of the first thin film transistor TR1 through a contact hole. Accordingly, a scan signal SS can be applied to the first gate electrode G1 of the first thin film transistor TR1.

A second bridge electrode BR22 is disposed on the passivation layer 180, and connects the driving power line PL and the second drain electrode D2 of the second thin film transistor TR2. In detail, referring to FIG. 18, a part of the second bridge electrode BR22 is connected to the driving power line PL through a contact hole, and another part of the second bridge electrode BR22 is connected to the second drain electrode D2 of the second thin film transistor TR2 through another contact hole. Accordingly, a driving voltage Vdd can be applied to the second drain electrode D2 of the second thin film transistor TR2.

A third bridge electrode BR23 is disposed on the passivation layer 180, and connects the first bridge electrode BR21, the second gate electrode G2 of the second thin film transistor TR2, and the second capacitor electrode CE2.

Since the first bridge electrode BR21 is connected to the first drain electrode D1 of the first thin film transistor TR1, the data voltage Vdata delivered to the first drain electrode D1 through the first thin film transistor TR1 can be applied to the second gate electrode G2 of the second thin film transistor TT2 via the first bridge electrode BR21 and the third bridge electrode BR23.

In addition, by the third bridge electrode BR23, a same voltage as the voltage of the second gate electrode G2 can be applied to the second capacitor electrode CE2.

As a result, a same voltage can be applied to the first drain electrode D1 of the first of thin film transistor TR1, the second gate electrode G2 of the second thin film transistor TR2, and the second capacitor electrode CE2.

A fourth bridge electrode BR24 is disposed on the passivation layer 180, and connects the light shielding layer 111 and the third capacitor electrode CE3. As a result, a same voltage as the voltage of the first capacitor electrode CE1 can be applied to the third capacitor electrode CE3. Referring to FIGS. 18 and 19, the third capacitor electrode CE3 can be subjected to the same voltage as the second source electrode S2 of the second thin film transistor TR2.

A first capacitor C1 can be formed by overlapping the first capacitor electrode CE1 and the second capacitor electrode CE2. A second capacitor C2 can be formed by overlapping the second capacitor electrode CE2 and the third capacitor electrode CE3. The total capacitor Ct is formed by the first capacitor C1 and the second capacitor C2.

A planarization layer 190 is disposed on the gate line GL and bridge electrodes BR22, BR23, BR24. The planarization layer 190 planarizes the upper portions of the first thin film transistor TR1 and the second thin film transistor TR2 and protects the first thin film transistor TR1 and the second thin film transistor TR2.

A first electrode 711 of the display element 710 is disposed on the planarization layer 190. The first electrode 711 of the display element 710 can contact the fourth bridge electrode BR24 through a contact hole formed in the planarization layer 190. As a result, the first electrode 711 can be connected to the second source electrode S2 of the second thin film transistor TR2.

A bank layer 750 is disposed at the edge of the first electrode 711. The bank layer 750 defines the light-emitting area of the display element 710.

An organic emission layer 712 is disposed on the first electrode 711, and a second electrode 713 is disposed on the organic emission layer 712. Accordingly, the display element 710 cab completed. The display element 710 illustrated in FIG. 19 is an organic light emitting diode OLED. Accordingly, the display apparatus 800 according to an embodiment of the present disclosure can be referred to as an organic light emitting display apparatus.

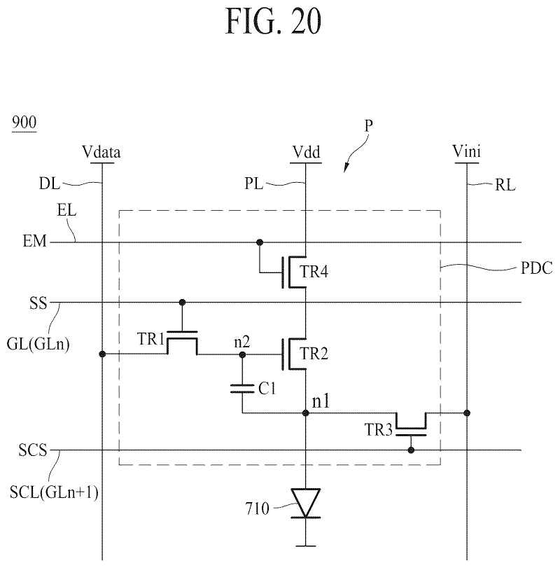

FIG. 20 is a circuit diagram of a pixel P of a display apparatus 900 according to another embodiment of the present disclosure.

The pixel P included in the display apparatus 900 of FIG. 20 includes an organic light emitting diode OLED, which is the display element 710, and a pixel driving circuit PDC that drives the display element 710. The display element 710 is connected to a pixel driving circuit PDC.

In the pixel P, signal lines DL, EL, GL, PL, SCL, and RL that supply signals to the pixel driving circuit PDC are disposed.

A data voltage Vdata is supplied to the data line DL, a scan signal SS is supplied to the gate line GL, and a driving voltage Vdd for driving the pixel is supplied to the driving power line PL. The reference voltage Vref is supplied to the reference line RL, and the sensing control signal SCS is supplied to the sensing control line SCL.

Referring to FIG. 20, the gate line of the ‘n’ th pixel P is designated as “GLn”, the gate line of the neighboring ‘n+1’ th pixel P, which is “GLn+1”, can serve as the sensing control line SCL of the ‘n’ th pixel P. Here, n is a real number such as a positive integer.

The pixel driving circuit PDC, for example, includes a first thin film transistor TR1 (switching transistor) connected with the gate line GL and the data line DL, a second thin film transistor TR2 (driving transistor) for controlling a magnitude of a current output to the display element 710 in accordance with the data voltage Vdata transmitted through the first thin film transistor TR1, and a third thin film transistor TR3 (sensing transistor) for sensing characteristics of the first thin film transistor TR1.

A capacitor C1 is positioned between the gate electrode of the second thin film transistor TR2 and the display element 710. The capacitor C1 disposed between the first node n1 and the second node n2 is also referred to as the storage capacitor Cst.

The first thin film transistor TR1 is turned on by the scan signal SS supplied to the gate line GL, and transmits the data voltage Vdata, which is supplied to the data line DL, to the gate electrode of the second thin film transistor TR2.

The third thin film transistor TR3 is connected to the first node n1 between the second thin film transistor TR2 and the display element 710, and connected to the reference line RL. The third thin film transistor TR3 is turned on or turned off by the sensing control signal SCS, and senses characteristics of the second thin film transistor TR2, which is a driving transistor, during the sensing period.

The second node n2, connected to the gate electrode of the second thin film transistor TR2, is connected to the first thin film transistor TR1.

When the first thin film transistor TR1 is turned on, the data voltage Vdata supplied through the data line DL is supplied to the gate electrode of the second thin film transistor TR2. The data voltage Vdata is charged in the capacitor C1 formed between the gate electrode and the source electrode of the second thin film transistor TR2.

An emission control signal EM is supplied to the emission control line EL.

The fourth thin film transistor TR4 is a light emission control transistor for controlling the timing of light emission by controlling the second thin film transistor TR2. The fourth thin film transistor TR4 transfers the driving voltage Vdd to the second thin film transistor TR2 or blocks the driving voltage Vdd according to the emission control signal EM. When the fourth thin film transistor TR4 is turned on, current is supplied to the second thin film transistor TR2, whereby light is emitted from the display element 710.

The pixel driving circuit PDC according to another embodiment of the present disclosure can be formed in various structures other than those described above. The pixel driving circuit PDC can include, for example, three thin film transistors or five or more thin film transistors. In addition, the pixel driving circuit PDC can include two or more of capacitors.

The present disclosure described above is not limited to the above-described embodiments and the accompanying drawings, and it is well known to those with ordinary knowledge that various substitutions, modifications, and changes are possible within the scope of the technical details of the present disclosure.

What is claimed is:

1. A thin film transistor comprising:
an active material layer on a base substrate; and
a gate electrode spaced apart from the active material layer and overlapping at least a part of the active material layer,
wherein the active material layer includes:
a channel portion overlapping the gate electrode;
a source connection portion contacting one side of the channel portion;
a drain connection portion contacting another side of the channel portion; and
an insulating portion contacting at least one of the source connection portion and the drain connection portion, and
wherein the channel portion, the source connection portion, the drain connection portion, and the insulating portion are disposed on a same layer.

2. The thin film transistor according to claim 1,
wherein the active material layer includes an oxide semiconductor material, and the insulating portion of the active material layer includes a first dopant.

3. The thin film transistor according to claim 2,
wherein the first dopant includes at least one of nitrogen (N), sulfur(S), chlorine (Cl), gallium (Ga), tungsten (W), iron (Fe), and tin (Sn).

4. The thin film transistor according to claim 2,
wherein each of the source connection portion and the drain connection portion includes a second dopant different from the first dopant.

5. The thin film transistor according to claim 4,
wherein the second dopant includes at least one of boron (B), phosphorus (P), fluorine (F) and hydrogen (H).

6. The thin film transistor according to claim 4,
wherein the insulating portion of the active material layer further includes the second dopant.

7. The thin film transistor according to claim 2,
wherein the oxide semiconductor material includes at least one of IGZO (InGaZnO)-based oxide semiconductor material, IGZTO (InGaZnSnO)-based oxide semiconductor material, IZO (InZnO)-based oxide semiconductor material, IGO (InGaO)-based oxide semiconductor material, ITO (InSnO)-based oxide semiconductor material, ITZO (InSnZnO)-based oxide semiconductor material, InO-based, ZnO-based oxide semiconductor material, and FIZO (FeInZnO)-based oxide semiconductor material.

8. The thin film transistor according to claim 1,
wherein the channel portion, the source connection portion, the drain connection portion, and the insulating portion are integrally formed.

9. The thin film transistor according to claim 1, further comprising a light shielding layer disposed between the base substrate and the active material layer and overlapping the channel portion.

10. The thin film transistor according to claim 9, further comprising a first capacitor electrode integrally formed with the light shielding layer and not overlapping the channel portion.

11. The thin film transistor according to claim 10,
wherein the active material layer includes a second capacitor electrode spaced apart from the channel portion,
wherein the second capacitor electrode is insulated from at least one of the source connection portion and the drain connection portion by the insulating portion, and
wherein the first capacitor electrode and the second capacitor electrode overlap each other to form a first capacitor.

12. The thin film transistor according to claim 3,
wherein the first dopant includes nitrogen (N), and
wherein the insulating portion of the active material layer includes 40 to 60 atomic % (at %) of oxygen and 4 to 10 atomic % (at %) of nitrogen based on a total number of atoms of the insulating portion.

13. The thin film transistor according to claim 3,
wherein the oxide semiconductor material includes gallium (Ga), and the first dopant includes gallium (Ga).

14. The thin film transistor according to claim 13,
wherein a concentration of gallium (Ga) included in the insulating portion is higher than a concentration of gallium (Ga) included in the channel portion, the source connection portion, or the drain connection portion.

15. The thin film transistor according to claim 2,
wherein the active material layer includes a first oxide semiconductor material layer, and a second oxide semiconductor material layer on the first oxide semiconductor material layer.

16. A thin film transistor substrate comprising:
a first thin film transistor and a second thin film transistor on a base substrate,
wherein the first thin film transistor and the second thin film transistor include an active material layer,
wherein the first thin film transistor includes:
a first channel portion on the base substrate;
a first source connection portion contacting one side of the first channel portion;
a first drain connection portion contacting another side of the first channel portion; and
a first gate electrode spaced apart from the active material layer and overlapping the first channel portion,
wherein the second thin film transistor includes:
a second channel portion on the base substrate;
a second source connection portion contacting one side of the second channel portion;
a second drain connection portion contacting another side of the second channel portion; and
a second gate electrode spaced apart from the active material layer and overlapping the second channel portion,
wherein the first thin film transistor and the second thin film transistor are spaced apart from each other with an insulating portion interposed therebetween,
wherein the active material layer includes the first channel portion, the first source connection portion, the first drain connection portion, the second channel portion, the second source connection portion, the second drain connection portion and the insulating portion, and
wherein the first channel portion, the first source connection portion, the first drain connection portion, the second channel portion, the second source connection portion, the second drain connection portion and the insulating portion are disposed on a same layer.

17. The thin film transistor substrate according to claim 16,
wherein the first channel portion, the first source connection portion, the first drain connection portion, the second channel portion, the second source connection portion, the second drain connection portion and the insulating portion are integrally formed.

18. The thin film transistor substrate according to claim 16,
wherein the first channel portion, the first source connection portion, the first drain connection portion, the second channel portion, the second source connection portion, the second drain connection portion and the insulating portion include an oxide semiconductor material, and
wherein the insulating portion further includes a first dopant.

19. The thin film transistor substrate according to claim 18,
wherein the first dopant includes at least one of nitrogen (N), sulfur(S), chlorine (Cl), gallium (Ga), tungsten (W), iron (Fe), and tin (Sn).

20. The thin film transistor substrate according to claim 18,
wherein the first source connection portion, the first drain connection portion, the second source connection portion and the second drain connection portion include a second dopant different from the first dopant.

21. A display apparatus comprising:
a plurality of pixels arranged on a base substrate,
wherein each of the plurality of pixels includes:
a display element; and
a pixel driving circuit to drive the display element,
wherein each pixel driving circuit includes the thin film transistor of claim 1.

22. The display apparatus according to claim 21,
wherein the active material layer is formed integrally over the plurality of pixels.

23. A method of manufacturing a thin film transistor, the method comprising:
forming an active material layer on a base substrate;
forming a mask on the active material layer;
forming an insulating portion by doping a first dopant into a part of the active material layer that does not overlap the mask;
forming a gate electrode spaced apart from the active material layer on the active material layer; and
forming a source connection portion and a drain connection portion by conductorizing parts of the active material layer not overlapping the gate electrode,
wherein a part of the active material layer overlapping the gate electrode forms a channel portion,
wherein the source connection portion is disposed between the channel portion and the insulating portion, and
wherein the drain connection portion is spaced apart from the source connection portion and disposed between the channel portion and the insulating portion.

24. The method according to claim 23,
wherein the first dopant includes at least one of nitrogen (N), sulfur(S), chlorine (Cl), gallium (Ga), tungsten (W), iron (Fe), and tin (Sn).

25. The method according to claim 23,
wherein the conductorization is performed by plasma treatment or doping with a second dopant.
